(19) United States
(12) Patent Application Publication
(10) Pub. No.: US 2026/0247688 A1
(43) Pub. Date: Aug. 20, 2026

(54) METHOD FOR MANUFACTURING SEMICONDUCTOR DEVICE

(71) Applicant: SAMSUNG ELECTRONICS CO., LTD., Suwon-si (KR)

(72) Inventors: Seung Seok HAN, Suwon-si (KR); Dong Ju KIM, Suwon-si (KR); Do Sun LEE, Suwon-si (KR); Sun Jung LEE, Suwon-si (KR); Ji Hwan LEE, Suwon-si (KR); Seung Keun CHA, Suwon-si (KR); Geun Myeong KIM, Suwon-si (KR); Hyeon Seok DO, Suwon-si (KR)

(73) Assignee: SAMSUNG ELECTRONICS CO., LTD., Suwon-si (KR)

(21) Appl. No.: 19/339,860

(22) Filed: Sep. 25, 2025

(30) Foreign Application Priority Data
Feb. 17, 2025 (KR) 10-2025-0020001

(51) Int. Cl. H10D 84/01; H10D 84/85

(52) U.S. Cl. CPC H10D 84/0186; H10D 84/0167; H10D 84/017; H10D 84/851; H10D 84/856

(57) ABSTRACT

A method for manufacturing a semiconductor device is provided. The method includes: providing a lower channel pattern, an intermediate insulating pattern, and an upper channel pattern, which are stacked sequentially on a substrate along a vertical direction; forming a lower source/drain pattern connected to the lower channel pattern; forming an upper source/drain pattern connected to the upper channel pattern; forming a gate structure which surrounds the lower channel pattern and the upper channel pattern; forming a contact hole extending into the upper source/drain pattern and the lower source/drain pattern; forming a contact film in the contact hole; and performing an annealing process on the contact film to form a front source/drain contact.

### CROSS-REFERENCE TO RELATED APPLICATION

This application claims priority from Korean Patent Application No. 10-2025-0020001, filed on Feb. 17, 2025, in the Korean Intellectual Property Office, the disclosure of which is incorporated by reference herein in its entirety.

### BACKGROUND

The present disclosure relates to a method for manufacturing a semiconductor device, and more specifically, to a method for manufacturing a semiconductor device including a Multi-Bridge Channel Field Effect Transistor (MBCFET™).

A multi gate transistor in which a multi-channel active pattern (or a silicon body) having a fin or nanowire shape is formed on a substrate and a gate is formed on a surface of the multi-channel active pattern has been proposed to increase density of a semiconductor device.

By utilizing a three-dimensional channel, scaling is easily performed. Further, even if a gate length of the multi gate transistor is not increased, the current control capability may be improved. Furthermore, a short channel effect (SCE) in which potential of a channel region is influenced by a drain voltage may be effectively suppressed.

Furthermore, in order to implement more elements in the same area, a semiconductor device using a stacked multi-gate transistor in which the multi-gate transistor of an upper region is stacked on a multi-gate transistor of a lower region, is being researched.

### SUMMARY

One or more embodiments provide a method for manufacturing a semiconductor device that may improve element performance and reliability.

According to an aspect of an embodiment, a method for manufacturing a semiconductor device, includes: providing a lower channel pattern, an intermediate insulating pattern, and an upper channel pattern, which are stacked sequentially on a substrate along a vertical direction; forming a lower source/drain pattern connected to the lower channel pattern; forming an upper source/drain pattern connected to the upper channel pattern; forming a gate structure which surrounds the lower channel pattern and the upper channel pattern; forming a contact hole extending into the upper source/drain pattern and the lower source/drain pattern; forming a contact film in the contact hole; and performing an annealing process on the contact film to form a front source/drain contact.

According to another aspect of an embodiment, a method for manufacturing a semiconductor device, includes: providing a lower channel pattern, an intermediate insulating pattern, and an upper channel pattern, which are stacked sequentially along a vertical direction; forming a lower source/drain pattern including a p-type dopant on a side face of the lower channel pattern; forming a lower front interlayer insulating film on the lower source/drain pattern; forming an upper source/drain pattern including an n-type dopant on a side face of the upper channel pattern, the lower front interlayer insulating film being between the lower source/drain pattern and the upper source/drain pattern; forming an upper front interlayer insulating film on the upper source/drain pattern; forming a gate structure that encloses the lower channel pattern and the upper channel pattern; forming a contact hole that penetrates the upper front interlayer insulating film and exposes the upper source/drain pattern, a bottom side of the contact hole being below an uppermost side of the upper channel pattern; forming a contact film in the contact hole; and performing an annealing process on the contact film to form a front source/drain contact.

According to another aspect of an embodiment, a method for manufacturing a semiconductor device, includes: providing a lower stacked structure including a first lower semiconductor layer and a second lower semiconductor layer stacked alternately along a vertical direction, on a substrate; forming an intermediate insulating pattern on the lower stacked structure; forming an upper stacked structure including a first upper semiconductor layer and a second upper semiconductor layer stacked alternately along the vertical direction, on the intermediate insulating pattern; forming a plurality of first recesses which penetrate the lower stacked structure, the intermediate insulating pattern, and the upper stacked structure; forming a lower source/drain pattern, a lower front interlayer insulating film, and an upper source/drain pattern which are stacked sequentially along the vertical direction, in each of the plurality of first recesses, the lower source/drain pattern including a first lower source/drain pattern and a second lower source/drain pattern in different first recesses of the plurality of first recesses, and the upper source/drain pattern including a first upper source/drain pattern on the first lower source/drain pattern, and a second upper source/drain pattern on the second lower source/drain pattern; removing the first lower semiconductor layer and the first upper semiconductor layer to form a gate trench; forming a gate structure which is provided in the gate trench; forming a first contact hole which exposes the first upper source/drain pattern and the first lower source/drain pattern; forming a second contact hole which exposes the second upper source/drain pattern; forming a contact film in the first contact hole and the second contact hole; and performing an annealing process on at least a part of the contact film to form a first front source/drain contact in the first contact hole and a second front source/drain contact in the second contact hole.

According to another aspect of an embodiment, a semiconductor device includes: a first lower source/drain pattern; a first upper source/drain pattern provided on the first lower source/drain pattern; a second lower source/drain pattern; a second upper source/drain pattern provided on the second lower source/drain pattern; a first front source/drain contact connected to the first upper/source/drain pattern and the first lower source/drain pattern; and a second front source/drain contact connected to the second upper/source/drain pattern. A first average crystal grain size of the first front source/drain contact and a second average crystal grain size of the second front source/drain contact are different.

The first average crystal grain size may be larger than the second average crystal grain size.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features will be more apparent from the following description of embodiments, taken in conjunction with the attached drawings, in which:

FIG. 1 is a layout diagram for of a semiconductor device according to some embodiments;

FIG. 2 is a cross-sectional view taken along A-A′ of FIG. 1 according to some embodiments;

FIG. 3 is a cross-sectional view taken along B-B′ of FIG. 1 according to some embodiments;

FIG. 4 is a cross-sectional view taken along C-C′ of FIG. 1 according to some embodiments;

FIGS. 5 to 8 are diagrams for explaining a semiconductor device according to some embodiments;

FIGS. 9 to 27 are diagrams for explaining a method for manufacturing a semiconductor device according to some embodiments;

FIG. 28 is a diagram for explaining the method for manufacturing the semiconductor device according to some embodiments;

FIG. 29 is a diagram for explaining the method for manufacturing the semiconductor device according to some embodiments;

FIG. 30 is a layout diagram for explaining the semiconductor device according to some embodiments;

FIG. 31 is a cross-sectional view taken along D-D′ of FIG. 30 according to some embodiments; and

FIG. 32 is a cross-sectional view taken along E-E′ of FIG. 30 according to some embodiments.

### DETAILED DESCRIPTION

Embodiments will be described more fully with reference to the accompanying drawings, in which example embodiments are shown. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. As used herein, the terms “1st” or “first” and “2nd” or “second” may use corresponding components regardless of importance or order and are used to distinguish a component from another component without limiting the components.

Although drawings of the semiconductor device according to some embodiments show a transistor including a nanowire or a nanosheet, and a Multi-Bridge Channel Field Effect Transistor (MBCFET™) as an example, embodiments are not limited thereto.

The semiconductor device according to some embodiments may include a fin-type transistor (FinFET) including a channel region of a fin-type pattern shape, a tunneling transistor (tunneling FET) or a vertical transistor (Vertical FET). The semiconductor device according to some embodiments may include a planar transistor. In addition, the technical idea of the present disclosure may be applied to a transistor based on two-dimensional material (2D material based FETs) and a heterostructure thereof. Further, the semiconductor device according to some embodiments may include a bipolar junction transistor, a laterally diffused metal oxide semiconductor (LDMOS), or the like.

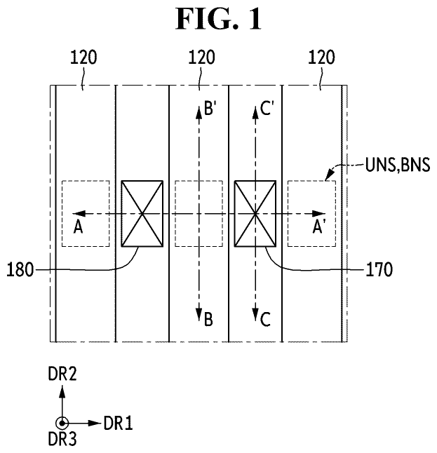

The semiconductor device according to some embodiments will be described referring to FIGS. 1 to 4.

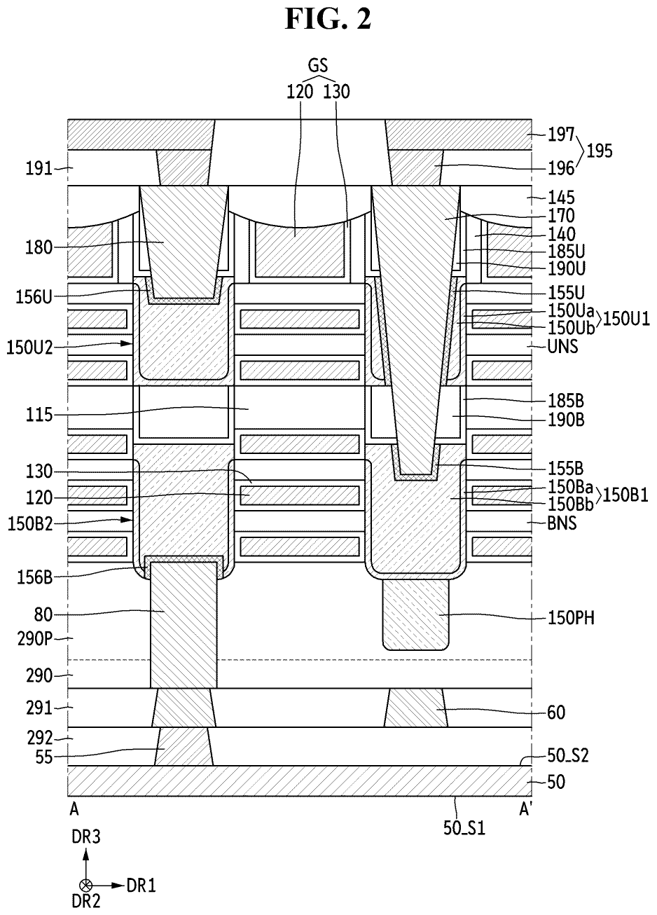

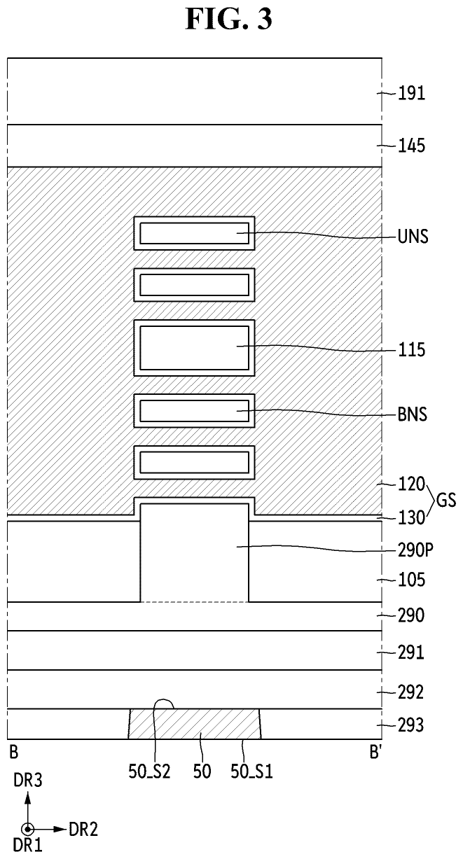

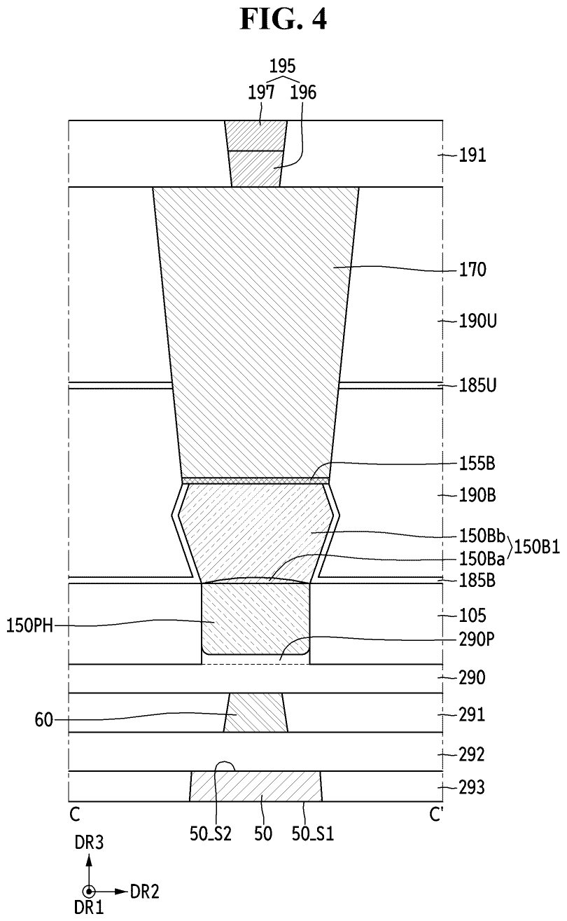

FIG. 1 is a layout diagram for describing the semiconductor device according to some embodiments. FIG. 2 is a cross-sectional view taken along A-A′ of FIG. 1. FIG. 3 is a cross-sectional view taken along B-B′ of FIG. 1. FIG. 4 is a cross-sectional view taken along C-C′ of FIG. 1.

Referring to FIGS. 1 to 4, the semiconductor device according to some embodiments may include a lower channel pattern BNS, an upper channel pattern UNS, a gate structure GS, lower source/drain patterns 150B1 and 150B2, upper source/drain patterns 150U1 and 150U2, an intermediate insulating pattern 115, a first front source/drain contact 170, a second front source/drain contact 180, a second back source/drain contact 80, and a back wiring line 50.

Hereinafter, a third direction DR3 may be orthogonal to a first direction DR1 and a second direction DR2. The second direction DR2 may be orthogonal to the first direction DR1. The first direction DR1 may be referred to as a first horizontal direction, the second direction DR2 may be referred to as a second horizontal direction, and the third direction DR3 may be referred to as a vertical direction. A top, a bottom, an upper side, a lower side, and a bottom side may be defined on the basis of the third direction DR3.

A back interlayer insulating film 290 may include an upper side and a bottom side that are opposite to each other in the third direction DR3. The back interlayer insulating film 290 may include, for example, at least one of silicon oxide, silicon nitride, silicon carbonitride, silicon oxynitride, and a low dielectric constant material. A dielectric constant of the low dielectric constant material may have a value less than 3.9, which is the dielectric constant of silicon oxide. Although the back interlayer insulating film 290 is shown as being a single film, embodiments are not limited thereto.

An insulating pattern 290P may be disposed on the upper side of the back interlayer insulating film 290. The insulating pattern 290P may protrude from the upper side of the back interlayer insulating film 290 in the third direction DR3. The insulating pattern 290P may extend in the first direction DR1. The insulating pattern 290P may include the same material as the back interlayer insulating film 290.

A field insulating film 105 may be disposed on the upper side of the back interlayer insulating film 290. The field insulating film 105 may surround the side wall of the insulating pattern 290P. For example, the upper side of the insulating pattern 290P may be formed to be higher than the upper side of the field insulating film 105. That is, at least a part of the insulating pattern 290P may protrude beyond the upper side of the field insulating film 105 in the third direction DR3. Also, as another example, the upper side of the insulating pattern 290P may be formed substantially on the same plane as the upper side of the field insulating film 105.

The field insulating film 105 may include, for example, an oxide film, a nitride film, an oxynitride film or a combined film thereof. For example, the field insulating film 105 may include the same material as the back interlayer insulating film 290 and the insulating pattern 290P, and there may be no interface division between the field insulating film 105 and the back interlayer insulating film 290, no interface division between the field insulating film 105 and the insulating pattern 290P, and no interface division between the back interlayer insulating film 290 and the insulating pattern 290P.

The lower channel pattern BNS may be disposed on the back interlayer insulating film 290. For example, the lower channel pattern BNS may be disposed on the upper side of the back interlayer insulating film 290. The plurality of lower channel patterns BNS may be spaced apart from each other in the third direction DR3. The plurality of lower channel patterns BNS spaced apart from each other in the third direction DR3 may be spaced apart from each other in the first direction DR1. Although two lower channel patterns BNS are shown as being disposed on the upper side of the back interlayer insulating film 290, embodiments are not limited thereto. In some embodiments, one or three or more lower channel patterns BNS may be disposed on the upper side of the back interlayer insulating film 290.

The upper channel pattern UNS may be disposed on the upper side of the back interlayer insulating film 290. The upper channel pattern UNS may be disposed on the lower channel pattern BNS. The lower channel pattern BNS may be disposed between the back interlayer insulating film 290 and the upper channel pattern UNS. The upper channel pattern UNS may be spaced apart from the lower channel pattern BNS in the third direction DR3. The plurality of upper channel patterns UNS may be spaced apart from each other in the third direction DR3. The plurality of upper channel patterns UNS spaced apart in the third direction DR3 may be spaced apart in the first direction DR1. Although two upper channel patterns UNS are shown as being disposed on the upper side of the back interlayer insulating film 290, embodiments are not limited thereto. In some embodiments, one or three or more upper channel patterns UNS may be disposed on the upper side of the back interlayer insulating film 290. Although the number of upper channel patterns UNS is shown to be the same as the number of lower channel patterns BNS, embodiments are not limited thereto.

Each of the lower channel pattern BNS and the upper channel pattern UNS may have the form of a nanosheet or a nanowire.

Each of the lower channel pattern BNS and the upper channel pattern UNS may include an elemental semiconductor material such as silicon or germanium. In addition, each of the lower channel pattern BNS and the upper channel pattern UNS may include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge), and tin (Sn), or a compound obtained by doping these elements with a group IV element. The group III-V compound semiconductor may be, for example, one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

As an example, the lower channel pattern BNS may include the same material as the upper channel pattern UNS. As another example, the lower channel pattern BNS may include a different material from the upper channel pattern UNS.

An intermediate insulating pattern 115 may be disposed between the lower channel pattern BNS and the upper channel pattern UNS. The intermediate insulating pattern 115 may be spaced apart from the lower channel pattern BNS in the third direction DR3. The intermediate insulating pattern 115 may be spaced apart from the upper channel pattern UNS in the third direction DR3.

The intermediate insulating pattern 115 may include an insulating material. For example, the intermediate insulating pattern 115 may include at least one of silicon nitride, silicon oxycarbonitride, silicon boron carbonitride, silicon carbonitride, silicon oxide, silicon oxynitride, and combinations thereof.

The plurality of gate structures GS may be disposed on the back interlayer insulating film 290. For example, each gate structure GS may be disposed on the upper side of the back interlayer insulating film 290. The gate structure GS may extend in the second direction DR2. The gate structures GS may be disposed to be spaced apart in the first direction DR1. The gate structures GS may be adjacent to each other in the first direction DR1.

The gate structure GS may enclose the lower channel pattern BNS and the upper channel pattern UNS. For example, in a cross-sectional view of the gate structure GS taken in the second direction DR2, the gate structure GS may enclose the periphery of the lower channel pattern BNS and the periphery of the upper channel pattern UNS. The gate structure GS may enclose the intermediate insulating pattern 115. For example, the gate structure GS may be in contact with the insulating pattern 290P. The gate structure GS may be in contact with the upper side of the insulating pattern 290P.

The gate structure GS may include a gate electrode 120 and a gate insulating film 130.

The gate electrode 120 may be disposed on the back interlayer insulating film 290. The gate electrode 120 may extend in the second direction DR2. The gate electrode 120 may enclose the lower channel pattern BNS, the upper channel pattern UNS, and the intermediate insulating pattern 115. In this regard, the lower channel pattern BNS, the upper channel pattern UNS, and the intermediate insulating pattern 115 may penetrate the gate electrode 120.

The gate electrode 120 may be disposed between adjacent lower channel patterns BNS, and between adjacent upper channel patterns UNS. The gate electrode 120 may be disposed between the lower channel pattern BNS and the back interlayer insulating film 290, between the lower channel pattern BNS and the intermediate insulating pattern 115, and between the upper channel pattern UNS and the intermediate insulating pattern 115.

The gate electrode 120 that encloses the lower channel pattern BNS and the upper channel pattern UNS is shown as being a single film, embodiments are not limited thereto. For example, the gate electrode 120 that encloses the lower channel pattern BNS may be distinguished from the gate electrode 120 that encloses the upper channel pattern UNS.

The gate electrode 120 may include at least one of a metal, a conductive metal nitride, a metal silicide, a doped semiconductor material, a conductive metal oxide, and a conductive metal oxynitride. The gate electrode 120 may include, for example, but is not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and the conductive metal oxynitride may include, but are not limited to, an oxidized form of the aforementioned materials.

The gate insulating film 130 may be disposed between the gate electrode 120 and the insulating pattern 290P. The gate insulating film 130 may be disposed between the gate electrode 120 and the field insulating film 105. The gate insulating film 130 may extend along an upper side of the field insulating film 105 and an upper side and a side face of the insulating pattern 290P that protrudes beyond the field insulating film 105 in the third direction DR3. The gate insulating film 130 may be in contact with the field insulating film 105 and the insulating pattern 290P.

The gate insulating film 130 may be disposed between the lower channel pattern BNS and the gate electrode 120, between the upper channel pattern UNS and the gate electrode 120, and between the intermediate insulating pattern 115 and the gate electrode 120. The gate insulating film 130 may be disposed along the periphery of the lower channel pattern BNS, the periphery of the upper channel pattern UNS, and the periphery of the intermediate insulating pattern 115. The gate electrode 120 is disposed on the gate insulating film 130.

The gate insulating film 130 may include at least one of silicon oxide, silicon oxynitride, silicon nitride or a high dielectric constant material having a dielectric constant larger than that of silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate. Although the gate insulating film 130 is shown as a single film, embodiments are not limited thereto.

The semiconductor device according to some embodiments may include a Negative Capacitance (NC) FET that uses a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. A thickness of the ferroelectric material film may be, for example, but is not limited to, 0.5 to 10 nm. Because a critical thickness that exhibits the ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. The gate insulating film 130 may have a stacked film structure in which the plurality of ferroelectric material films and the plurality of paraelectric material films are alternately stacked.

The gate spacer 140 may be disposed on the upper side of the back interlayer insulating film 290. The gate spacer 140 may be disposed on the side wall of the gate electrode 120. The gate spacer 140 may not be disposed between the back interlayer insulating film 290 and the lower channel pattern BNS, and between the lower channel pattern BNS adjacent to each other in the third direction DR3. The gate spacer 140 may not be disposed between the intermediate insulating pattern 115 and the upper channel pattern UNS, and between the upper channel pattern UNS adjacent to each other in the third direction DR3. The gate spacer 140 may not be disposed between the intermediate insulating pattern 115 and the lower channel pattern BNS.

The gate spacer 140 may include, for example, at least one of silicon nitride, silicon oxynitride, silicon oxide, silicon oxycarbonitride, silicon boronitride, silicon oxyboronitride, silicon oxycarbide, and combinations thereof. Although the gate spacers 140 are each shown as being a single film, embodiments are not limited thereto.

A gate capping pattern 145 may be disposed on an upper side of the gate electrode 120. The upper side of the gate capping pattern 145 may be disposed on the same plane as an upper side of the upper interlayer insulating film 190U. In some embodiments, the gate capping pattern 145 may be disposed between the gate spacers 140.

The gate capping pattern 145 may include at least one of, for example, silicon nitride (SiN), silicon oxynitride (SiON), silicon carbonitride (SiCN), silicon oxycarbonitride (SiOCN), and combinations thereof. The gate capping pattern 145 may include a material having an etching selectivity with respect to the upper interlayer insulating film 190U.

The semiconductor device according to some embodiments may further include a gate contact electrically connected to the gate electrode 120. For example, the gate contact may extend in the third direction DR3, and penetrate the gate capping pattern 145 on the upper side of the gate electrode 120. The gate contact may be in contact with the upper side of the gate electrode 120. As another example, the gate contact may extend in the third direction DR3, and penetrate the gate insulating film 130 on the lower side of the gate electrode 120. The gate contact may be in contact with the lower side of the gate electrode 120. The gate contact may include, for example, at least one of a metal, a conductive metal nitride, a conductive metal carbide, a conductive metal oxide, a conductive metal carbonitride, and a two-dimensional material.

The lower source/drain patterns 150B1 and 150B2 may be disposed on the back interlayer insulating film 290. The lower source/drain patterns 150B1 and 150B2 may be disposed on at least one side of the gate electrode 120. For example, the lower source/drain patterns 150B1 and 150B2 may be disposed on both sides of the gate electrode 120.

The lower source/drain patterns 150B1 and 150B2 are connected to the lower channel pattern BNS. The lower source/drain patterns 150B1 and 150B2 are in contact with the lower channel pattern BNS. The uppermost sides of the lower source/drain patterns 150B1 and 150B2 may be formed to be higher than the uppermost side of the lower channel pattern BNS. The gate insulating film 130 may be disposed between the gate electrode 120 and the lower source/drain patterns 150B1 and 150B2.

The upper source/drain patterns 150U1 and 150U2 may be disposed on the lower source/drain patterns 150B1 and 150B2. The upper source/drain patterns 150U1 and 150U2 may be spaced apart from the lower source/drain patterns 150B1 and 150B2 in the third direction DR3. The upper source/drain patterns 150U1 and 150U2 may be disposed on at least one side of the gate electrode 120. For example, the upper source/drain patterns 150U1 and 150U2 may be disposed on both sides of the gate electrode 120.

The upper source/drain patterns 150U1 and 150U2 are connected to the upper channel pattern UNS. The upper source/drain patterns 150U1 and 150U2 are in contact with the upper channel pattern UNS. The uppermost sides of the upper source/drain patterns 150U1 and 150U2 may be formed to be higher than the uppermost side of the upper channel pattern UNS. The gate insulating film 130 may be disposed between the gate electrode 120 and the upper source/drain patterns 150U1 and 150U2.

Although the lower source/drain patterns 150B1 and 150B2 are shown to have a shape similar to a hexagon in FIG. 4, embodiments are not limited thereto. In some embodiments, the external shapes of the lower source/drain patterns 150B1 and 150B2 may be a shape similar to a pentagon or a rectangle.

Each of the lower source/drain patterns 150B1 and 150B2 and the upper source/drain patterns 150U1 and 150U2 may include a semiconductor material. For example, each of the lower source/drain patterns 150B1 and 150B2 and the upper source/drain patterns 150U1 and 150U2 may include silicon or germanium, which are elemental semiconductor materials. In addition, each of the lower source/drain patterns 150B1 and 150B2 and the upper source/drain patterns 150U1 and 150U2 may include, for example, a binary compound or a ternary compound including at least two of carbon (C), silicon (Si), germanium (Ge), and tin (Sn), or a compound formed by doping these elements with a group IV element.

The lower source/drain patterns 150B1 and 150B2 may be included in the source/drain of a transistor that uses the lower channel pattern BNS as a channel region. The upper source/drain patterns 150U1 and 150U2 may be included in the source/drain of a transistor that uses the upper channel pattern UNS as a channel region.

The lower channel pattern BNS and the upper channel pattern UNS may be included in transistors of different conductivity types. The lower source/drain patterns 150B1 and 150B2 include a dopant of a first conductivity type, and the upper source/drain patterns 150U1 and 150U2 may include a dopant of a second conductivity type different from the first conductivity type. The lower channel pattern BNS may be used as a channel region of a p-type metal-oxide-semiconductor field-effect transistor (PMOSFET), and the upper channel pattern UNS may be used as a channel region of an n-type metal-oxide-semiconductor field-effect transistor (NMOSFET). The lower source/drain patterns 150B1 and 150B2 may include a p-type dopant, and the upper source/drain patterns 150U1 and 150U2 may include an n-type dopant.

The p-type dopant may include, but is not limited to, at least one of boron (B) and gallium (Ga). The n-type dopant may include, but is not limited to, at least one of phosphorus (P), arsenic (As), antimony (Sb), and bismuth (Bi).

In some embodiments, each of the lower source/drain patterns 150B1 and 150B2 may include a first lower epitaxial film 150Ba and a second lower epitaxial film 150Bb, and each of the upper source/drain patterns 150U1 and 150U2 may include a first upper epitaxial film 150Ua and a second upper epitaxial film 150Ub.

For example, the first lower epitaxial film 150Ba may extend along the upper side of the insulating pattern 290P, the side face of the lower channel pattern BNS, and the side face of the gate structure GS. The second lower epitaxial film 150Bb may be stacked on the first lower epitaxial film 150Ba. The first lower epitaxial film 150Ba may be provided as a seed layer for growing the second lower epitaxial film 150Bb. The dopant concentration of the second lower epitaxial film 150Bb may be greater than the dopant concentration of the first lower epitaxial film 150Ba. The first upper epitaxial film 150Ua may extend along the upper side of the intermediate insulating pattern 115, the side face of the upper channel pattern UNS, and the side face of the gate structure GS. The second upper epitaxial film 150Ub may be stacked on the first upper epitaxial film 150Ua. The first upper epitaxial film 150Ua may be provided as a seed layer for growing the second upper epitaxial film 150Ub. The dopant concentration of the second upper epitaxial film 150Ub may be greater than the dopant concentration of the first upper epitaxial film 150Ua.

Although the lower source/drain patterns 150B1 and 150B2 and the upper source/drain patterns 150U1 and 150U2 are each shown to be multiple films in the drawings, embodiments are not limited thereto.

A lower front interlayer insulating film 190B may be disposed on the upper side of the back interlayer insulating film 290. The lower front interlayer insulating film 190B may cover the lower source/drain patterns 150B1 and 150B2. The upper source/drain patterns 150U1 and 150U2 may be disposed on the lower front interlayer insulating film 190B. The lower front interlayer insulating film 190B may be disposed between the lower source/drain patterns 150B1 and 150B2 and the upper source/drain patterns 150U1 and 150U2.

A lower source/drain etching stop film 185B may extend along the profile of the lower source/drain patterns 150B1 and 150B2. The lower source/drain etching stop film 185B may be disposed between the field insulating film 105 and the first lower front interlayer insulating film 190B. The lower source/drain etching stop film 185B may extend along the profile of the upper side of the field insulating film 105.

In some embodiments, the lower source/drain etching stop film 185B may not be disposed between the lower source/drain patterns 150B1 and 150B2 and the lower front interlayer insulating film 190B.

The upper front interlayer insulating film 190U may be disposed on the lower front interlayer insulating film 190B. The upper front interlayer insulating film 190U may cover the upper source/drain patterns 150U1 and 150U2.

The upper source/drain etching stop film 185U may be disposed between the upper front interlayer insulating film 190U and the upper source/drain patterns 150U1 and 150U2. The upper source/drain etching stop film 185U may extend along at least a part of the profiles of the upper source/drain patterns 150U1 and 150U2.

In some embodiments, in the cross-sectional view such as FIG. 4, the upper front interlayer insulating film 190U and the lower front interlayer insulating film 190B may not be separated by the upper source/drain etching stop film 185U.

Each of the lower front interlayer insulating film 190B and the upper front interlayer insulating film 190U may include at least one of, for example, silicon oxide, silicon nitride, silicon oxynitride, and a low dielectric constant material. Each of the lower source/drain etching stop film 185B and the upper source/drain etching stop film 185U may include at least one of, for example, silicon nitride, silicon oxynitride, silicon oxycarbonitride, silicon boronitride, silicon oxyboronitride, silicon carbonitride, silicon oxycarbide, and combinations thereof.

Front source/drain contacts 170 and 180 may be disposed on the upper source/drain patterns 150U1 and 150U2. The front source/drain contacts 170 and 180 may include a first front source/drain contact 170 connected to the upper source/drain pattern 150U1 and the lower source/drain pattern 150B1, and a second front source/drain contact 180 connected to the upper source/drain pattern 150U2. An average crystal grain size of the first front source/drain contact 170 may be larger than an average crystal grain size of the second front source/drain contact 180.

For example, the lower source/drain patterns 150B1 and 150B2 may include a first lower source/drain pattern 150B1 and a second lower source/drain patterns 150B2 different from each other. The upper source/drain patterns 150U1 and 150U2 may include a first upper source/drain pattern 150U1 on the first lower source/drain pattern 150B1, and a second source/drain pattern 150U2 on the second lower source/drain pattern 150B2. The front source/drain contacts 170 and 180 may include a first front source/drain contact 170 connected to the first upper source/drain pattern 150U1 and the first lower source/drain pattern 150B1, and a second front source/drain contact 180 connected to the second upper source/drain pattern 150U2.

The first front source/drain contact 170 is disposed on the upper side of the back interlayer insulating film 290. The first front source/drain contact 170 may extend in the third direction DR3. The first front source/drain contact 170 may extend into the first upper source/drain pattern 150U1, the lower front interlayer insulating film 190B, and the first lower source/drain pattern 150B1. The first front source/drain contact 170 may be disposed in the upper front interlayer insulating film 190U, the first upper source/drain pattern 150U1, the lower front interlayer insulating film 190B, and the first lower source/drain pattern 150B1. A part of the first front source/drain contact 170 may be disposed in the first lower source/drain pattern 150B1. The first front source/drain contact 170 may overlap the upper channel pattern UNS in the first direction DR1.

The first front source/drain contact 170 is electrically connected to the first upper source/drain pattern 150U1 and the first lower source/drain pattern 150B1. The first upper source/drain pattern 150U1 and the first lower source/drain pattern 150B1 are electrically connected by the first front source/drain contact 170.

A first upper contact silicide film 155U may be disposed between the first front source/drain contact 170 and the first upper source/drain pattern 150U1. The first upper contact silicide film 155U may be in contact with the first front source/drain contact 170.

A first lower contact silicide film 155B may be disposed between the first front source/drain contact 170 and the first lower source/drain pattern 150B1. The first lower contact silicide film 155B may be in contact with the first front source/drain contact 170.

The second front source/drain contact 180 is disposed on the upper side of the back interlayer insulating film 290. The second front source/drain contact 180 may extend in the third direction DR3. The second front source/drain contact 180 may extend into the second upper source/drain pattern 150U2. The second front source/drain contact 180 may be disposed in the upper front interlayer insulating film 190U and the second upper source/drain pattern 150U2. A part of the first front source/drain contact 170 may be disposed in the second upper source/drain pattern 150U2. The second front source/drain contact 180 is electrically connected to the second upper source/drain pattern 150U2. At least a part of the second front source/drain contact 180 may overlap the upper channel pattern UNS in the first direction DR1.

A second upper contact silicide film 156U may be disposed between the second front source/drain contact 180 and the second upper source/drain pattern 150U2. The second upper contact silicide film 156U may be in contact with the second front source/drain contact 180.

Each of the first and second front source/drain contacts 170 and 180 is shown to have a single conductive film structure, but embodiments are not limited thereto. In some embodiments, each of the first and second front source/drain contacts 170 and 180 may have multiple conductive film structures including a front contact barrier film and a front contact filling film.

Each of the first and second front source/drain contacts 170 and 180 may include at least one of, for example, a metal, a conductive metal nitride, a conductive metal carbide, a conductive metal oxide, a conductive metal carbonitride, and a two-dimensional material. Each of the first upper contact silicide film 155U and the second upper contact silicide film 156U may include a metal silicide material.

In some embodiments, each of the first and second front source/drain contacts 170 and 180 may include no seam or void inside.

A front insulating film 191 may be disposed on the upper front interlayer insulating film 190U, the gate structure GS, the first front source/drain contact 170, and the second front source/drain contact 180. The front insulating film 191 may include, for example, at least one of silicon oxide, silicon nitride, silicon carbonitride, silicon oxynitride, and a low dielectric constant material.

A front wiring structure 195 may be disposed in the front insulating film 191. The front wiring structure 195 may include a front via plug 196 and a front wiring line 197.

The front wiring structure 195 may be electrically connected to the first and second front source/drain contacts 170 and 180. The first front source/drain contact 170 may be disposed between the front wiring structure 195 and the first lower source/drain pattern 150B1. The first front source/drain contact 170 may electrically connect the first lower source/drain pattern 150B1, the first upper source/drain pattern 150U1, and the front wiring structure 195. The second front source/drain contact 180 may be disposed between the front wiring structure 195 and the second upper source/drain pattern 150U2. The second front source/drain contact 180 may electrically connect the front wiring structure 195 and the second upper source/drain pattern 150U2. The first and second front source/drain contacts 170 and 180 may be electrically connected to front wiring lines 197 different from each other.

Each of the front via plug 196 and the front wiring line 197 may include at least one of, for example, a metal, a conductive metal nitride, a conductive metal carbide, a conductive metal oxide, a conductive metal carbonitride, and a two-dimensional material.

Although each of the front via plug 196 and the front wiring line 197 is shown as being a single conductive film structure, embodiments are not limited thereto. In some embodiments, as an example, at least one of the front via plug 196 and the front wiring line 197 may have multiple conductive film structures including a barrier film and a filling film. As another example, the front wiring structure 195 may have an integral structure with no interface division between the front via plug 196 and the front wiring line 197.

In some embodiments, a sacrificial pattern 150PH may be disposed below the first lower source/drain pattern 150B1. The first lower source/drain pattern 150B1 may be disposed on the sacrificial pattern 150PH. The sacrificial pattern 150PH may be disposed inside the insulating pattern 290P. The sacrificial pattern 150PH may include a semiconductor material.

The second back source/drain contact 80 may be disposed between the second lower source/drain pattern 150B2 and the back wiring line 50. The second back source/drain contact 80 may overlap the second lower source/drain pattern 150B2 in the third direction DR3. The second back source/drain contact 80 may extend in the third direction DR3. The second back source/drain contact 80 may be electrically connected to the second lower source/drain pattern 150B2.

The second back source/drain contact 80 may electrically connect the second lower source/drain pattern 150B2 and the back wiring line 50. The second back source/drain contact 80 may be electrically connected to the back wiring line 50. The second lower source/drain pattern 150B2 that is not connected to the first front source/drain contact 170 may be electrically connected to the back wiring line 50.

The second back source/drain contact 80 may be disposed inside the back interlayer insulating film 290 and the second lower source/drain pattern 150B2. A part of the second back source/drain contact 80 may be disposed inside the second lower source/drain pattern 150B2.

A second lower contact silicide film 156B may be disposed between the second back source/drain contact 80 and the second lower source/drain pattern 150B2. The second lower contact silicide film 156B may be in contact with the second back source/drain contact 80.

The second back source/drain contact 80 is shown to have a single conductive film structure, but is not limited thereto. In some embodiments, the second back source/drain contact 80 may have multiple conductive film structures.

The second back source/drain contact 80 may include, for example, at least one of a metal, a conductive metal nitride, a conductive metal carbide, a conductive metal oxide, a conductive metal carbonitride, and a two-dimensional material. The second lower contact silicide film 156B may include a metal silicide material.

A first back insulating film 291, a second back insulating film 292, and a third back insulating film 293 may be disposed on the back interlayer insulating film 290. The first back insulating film 291, the second back insulating film 292, and the third back insulating film 293 may be sequentially disposed on a lower side of the back interlayer insulating film 290.

Each of the first back insulating film 291, the second back insulating film 292, and the third back insulating film 293 may include at least one of, for example, silicon oxide, silicon nitride, silicon carbonitride, silicon oxynitride, and a low dielectric constant material. Although each of the first back insulating film 291, the second back insulating film 292, and the third back insulating film 293 is shown to be a single film, embodiments are not limited thereto.

A back connecting contact 60 may be disposed inside the first back insulating film 291. The back connecting contact 60 may be electrically connected to the second back source/drain contact 80. The second back source/drain contact 80 may be disposed between the back connecting contact 60 and the second lower source/drain pattern 150B2.

A back connecting via 55 may be disposed inside the second back insulating film 292. The back connecting via 55 may be electrically connected to the back connecting contact 60. The back connecting contact 60 may be disposed between the back connecting via 55 and the second back source/drain contact 80. The back connecting via 55 may be electrically connected to the second lower source/drain pattern 150B2.

Although each of the back connecting via 55 and the back connecting contact 60 is shown to have a single conductive film structure, embodiments are not limited thereto. In some embodiments, at least one of the back connecting via 55 and the back connecting contact 60 may have multiple conductive film structures.

Each of the back connecting via 55 and the back connecting contact 60 may include, for example, at least one of a metal, a conductive metal nitride, a conductive metal carbide, a conductive metal oxide, a conductive metal carbonitride, and a two-dimensional material.

The back wiring line 50 may be disposed inside the third back insulating film 293. For example, the back wiring line 50 may extend in the first direction DR1.

As an example, the back wiring line 50 may be a power line that supplies power to the semiconductor device. As another example, the back wiring line 50 may be a signal line that supplies an operating signal of the semiconductor device.

The back wiring line 50 may include a first side 50_S1 and a second side 50_S2 that are opposite to each other in the third direction DR3. The lower channel pattern BNS, the upper channel pattern UNS, and the gate electrode 120 may be disposed on the second side 50_S2 of the back wiring line 50. The second back source/drain contact 80 may be connected to the second side 50_S2 of the back wiring line 50.

Although the back wiring line 50 is shown to have a single conductive film structure, embodiments are not limited thereto. In some embodiments, the back wiring line 50 may have multiple conductive film structures including a wiring barrier film and a wiring filling film. In such a case, the wiring filling film may fill a wiring filling film trench defined by the wiring barrier film.

The back wiring line 50 may include, for example, at least one of a metal, a conductive metal nitride, a conductive metal carbide, a conductive metal oxide, a conductive metal carbonitride, and a two-dimensional material. The two-dimensional material may include a 2D allotrope or a 2D compound, and may include, but is not limited to, at least one of graphene, boron nitride (BN), molybdenum sulfide, molybdenum selenide, tungsten sulfide, tungsten selenide, and tantalum sulfide. That is, because the above-mentioned 2D materials are only listed by way of example, the 2D materials that may be included in the semiconductor device of the present disclosure are not limited by the above-mentioned materials.

In some embodiments, the back wiring lines 50 may extend in the second direction DR2. In such a case, the shapes of the cross-sectional views taken along A-A′, B-B′, and C-C′ of FIG. 1 may vary.

In some embodiments, the back wiring line 50 may include a line portion and a via portion. The line portion of the back wiring line 50 may extend long in the first direction DR1. The via portion of the back wiring line 50 may protrude from the line portion of the back wiring line 50 in the third direction DR3. The via portion of the back wiring line 50 may protrude toward the second back source/drain contact 80.

In some embodiments, at least one of the back connecting contact 60 and the back connecting via 55 may not be disposed between the second back source/drain contact 80 and the back wiring line 50.

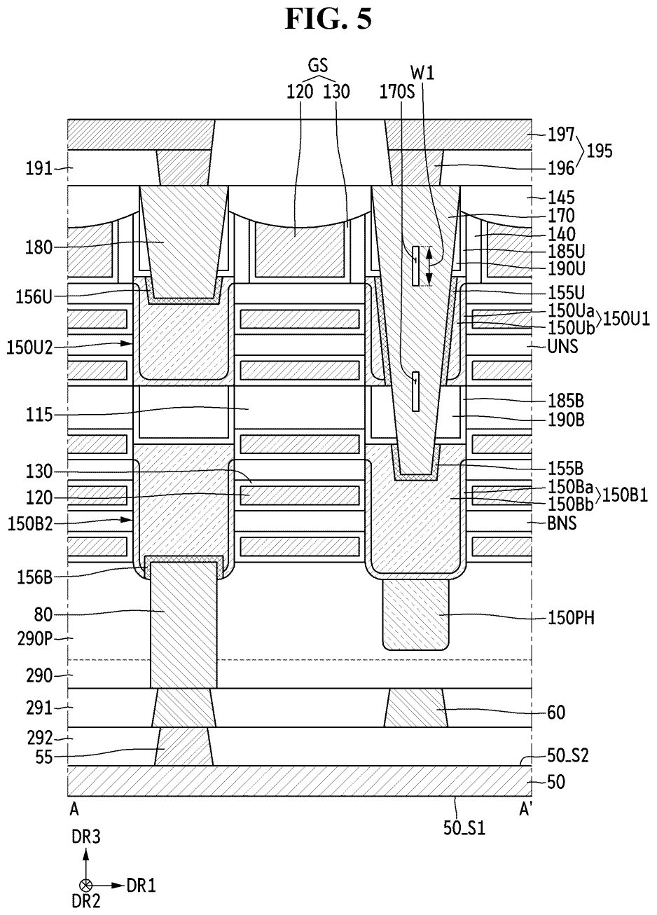

FIGS. 5 to 8 are diagrams for explaining a semiconductor device according to some embodiments. For reference, FIGS. 5 to 8 are cross-sectional views taken along A-A′ of FIG. 1. For convenience of explanation, differences from contents described using FIGS. 1 to 4 will be mainly described.

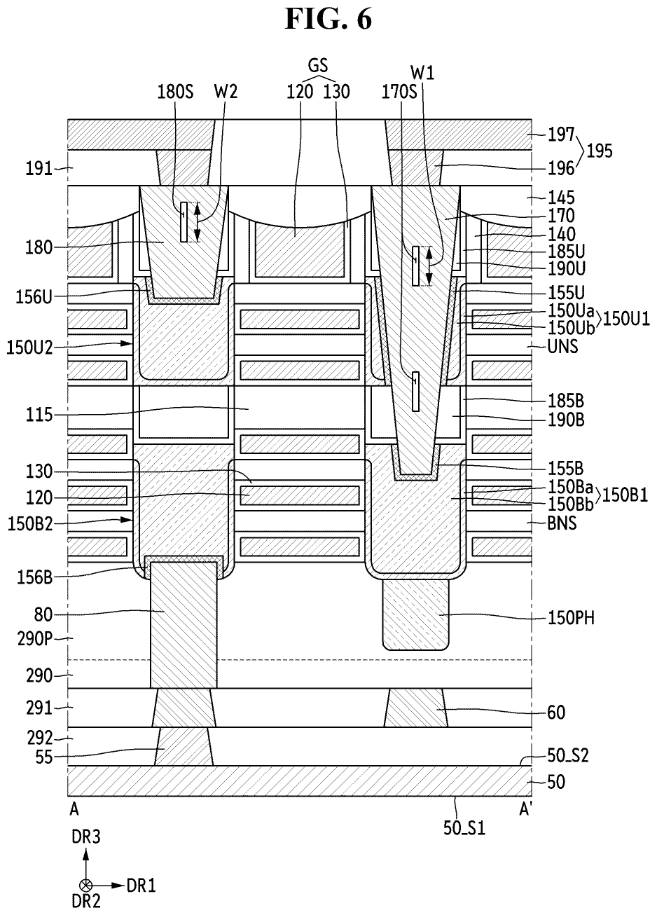

Referring to FIGS. 5 and 6, in the semiconductor device according to some embodiments, the first front source/drain contact 170 may include at least one first seam 170S therein. The first seam 170S may have a first size W1 in the third direction DR3. For example, the first front source/drain contact 170 may include a plurality of first seams 170S spaced apart in the third direction DR3 therein. As another example, the first front source/drain contact 170 may include one first seam 170S therein.

Referring to FIG. 5, in some embodiments, the second front source/drain contact 180 may not include a seam therein.

Referring to FIG. 6, in some embodiments, the second front source/drain contact 180 may include at least one second seam 180S therein. The second seam 180S may have a second size W2 in the third direction DR3.

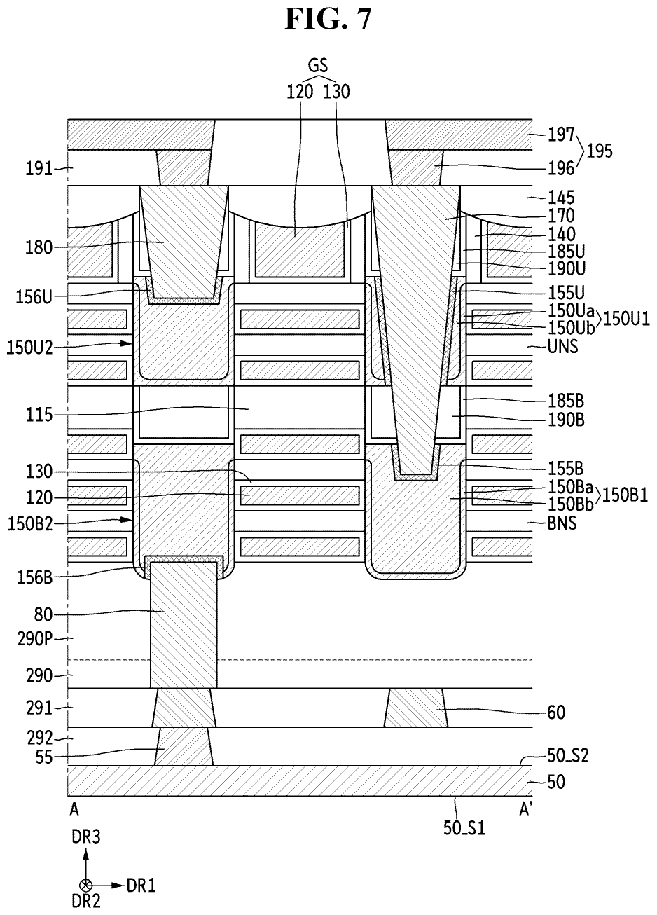

Referring to FIG. 7, the sacrificial pattern (150PH of FIG. 2) may be omitted in the semiconductor device according to some embodiments. The first lower source/drain pattern 150B1 may be disposed on the insulating pattern 290P.

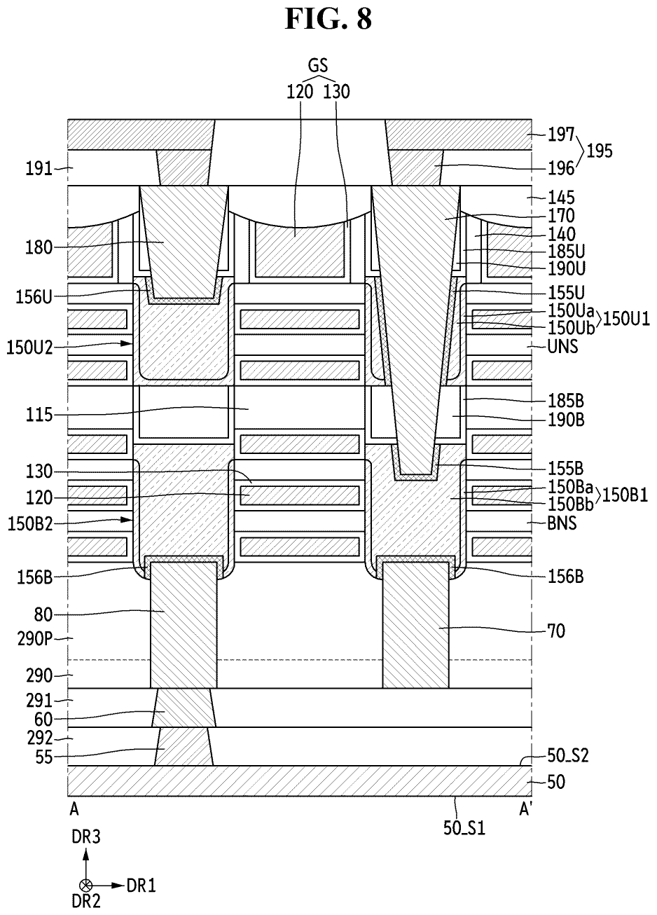

Referring to FIG. 8, the semiconductor device according to some embodiments may further include a first back source/drain contact 70.

The first back source/drain contact 70 may be disposed between the first lower source/drain pattern 150B1 and the back wiring line 50. The first back source/drain contact 70 may overlap the first lower source/drain pattern 150B1 in the third direction DR3. The first back source/drain contact 70 may extend in the third direction DR3.

The first back source/drain contact 70 may be electrically connected to the first lower source/drain pattern 150B1. The first back source/drain contact 70 may not be electrically connected to the back wiring line 50. The first lower source/drain pattern 150B1 connected to the first front source/drain contact 170 may not be electrically connected to the back wiring line 50.

The second lower contact silicide film 156B may be disposed between the first back source/drain contact 70 and the first lower source/drain pattern 150B1. The second lower contact silicide film 156B may be in contact with the first back source/drain contact 70.

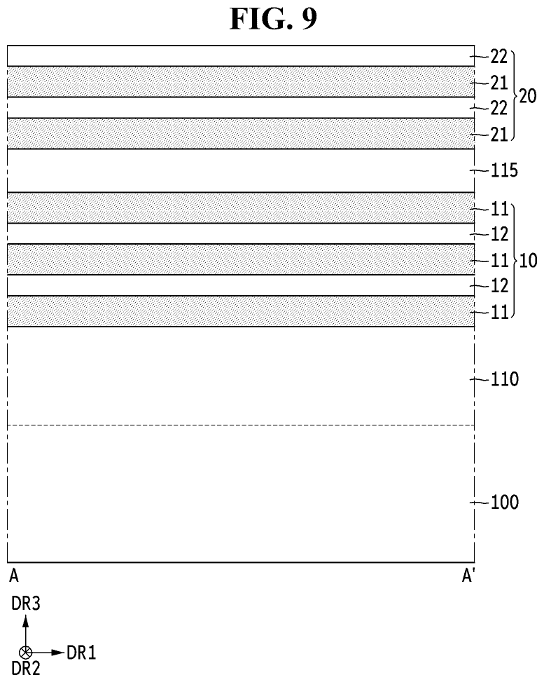

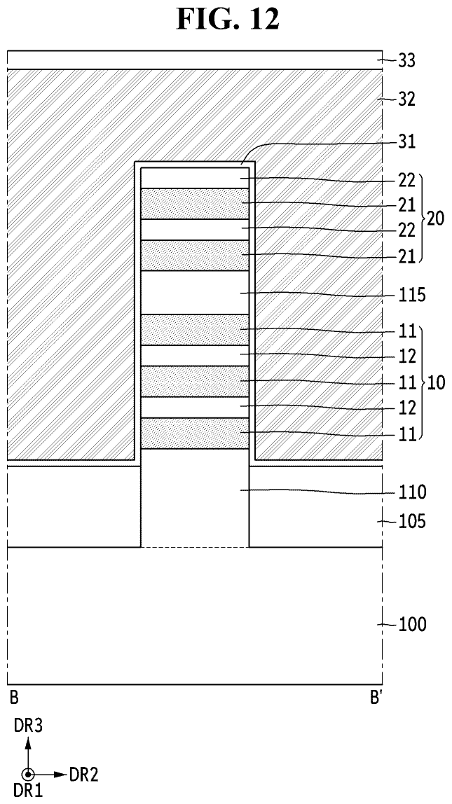

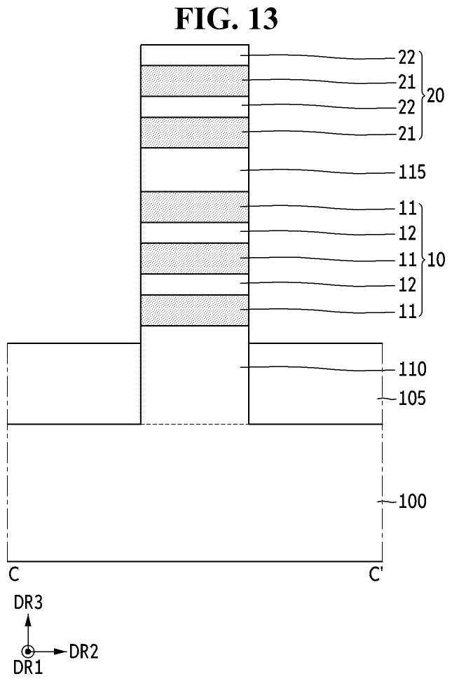

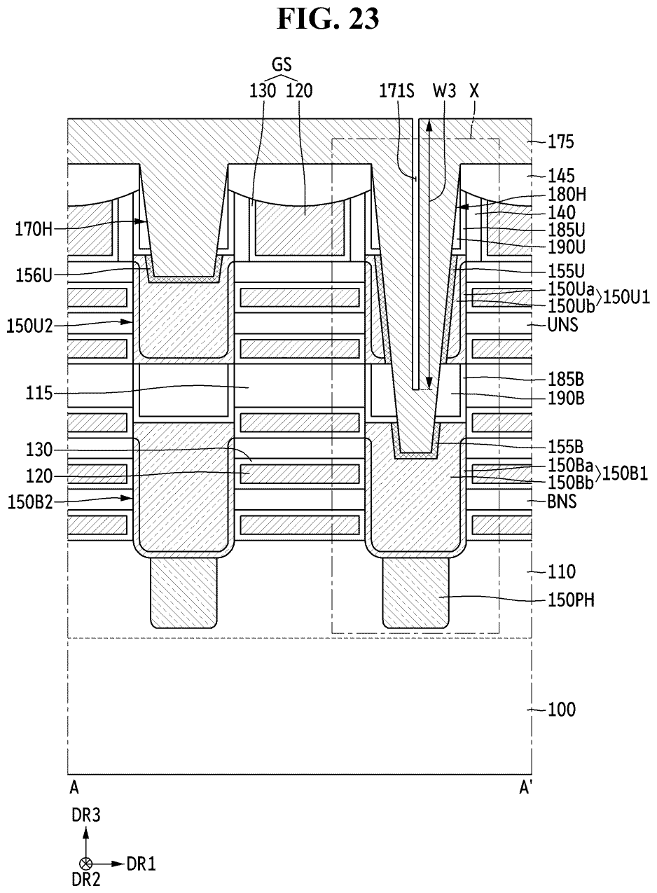

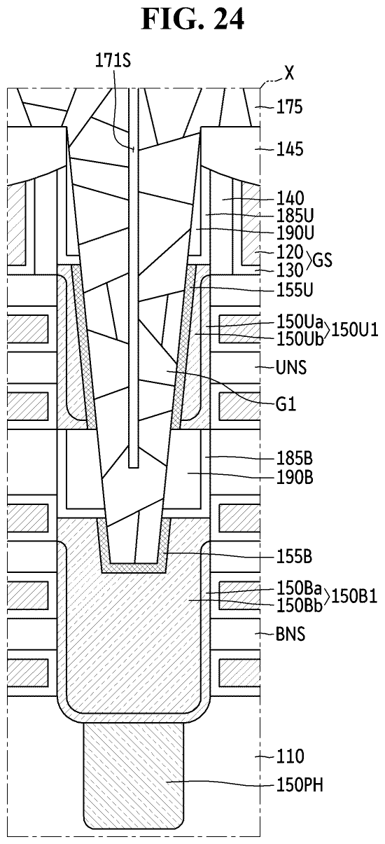

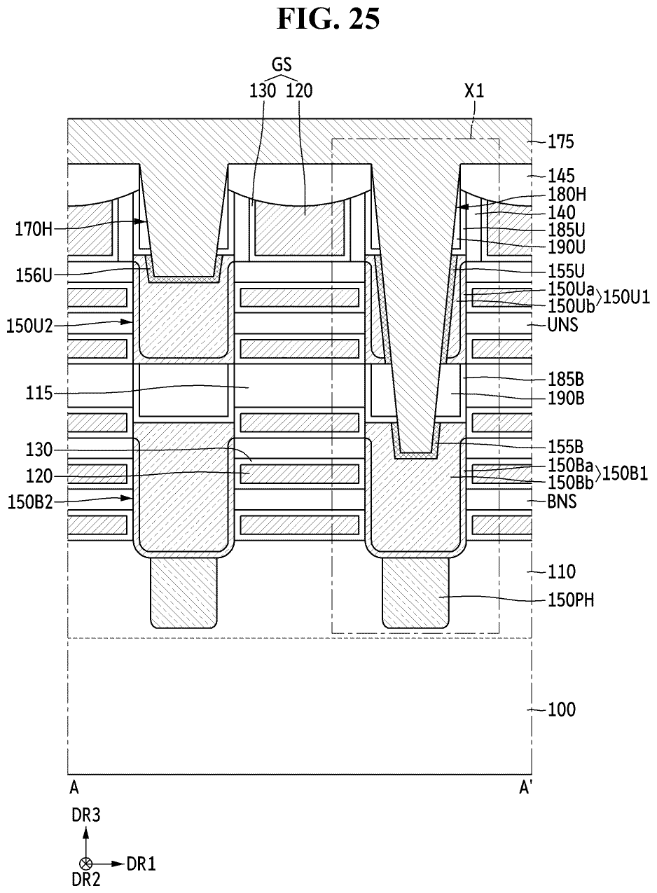

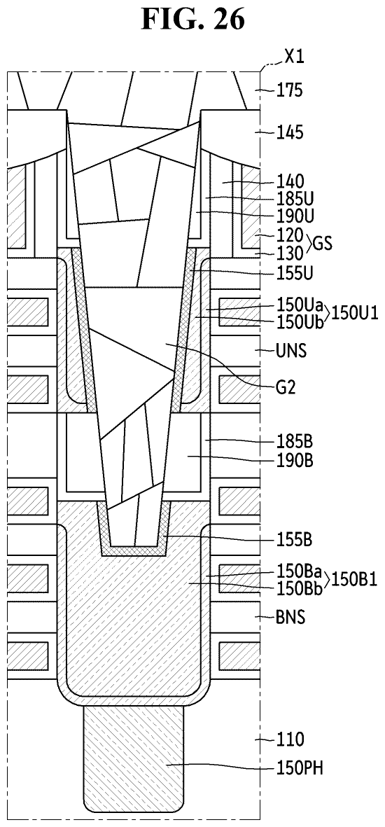

FIGS. 9 to 27 are diagrams for explaining a method for manufacturing a semiconductor device according to some embodiments. For convenience of explanation, differences from the contents explained using FIGS. 1 to 4 will be mainly explained. For reference, FIG. 24 is an enlarged view of a region X of FIG. 23, and FIG. 26 is an enlarged view of a region X1 of FIG. 25.

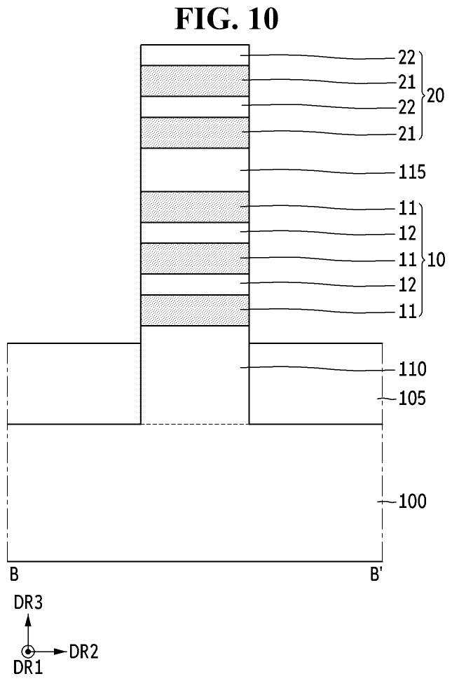

Referring to FIGS. 9 and 10, a lower stacked structure 10, an intermediate insulating pattern 115, and an upper stacked structure 20 may be formed on the substrate 100. The lower stacked structure 10, the intermediate insulating pattern 115, and the upper stacked structure 20 may be stacked sequentially on the substrate 100 along the third direction DR3. The lower stacked structure 10, the intermediate insulating pattern 115, and the upper stacked structure 20 may extend long in the first direction DR1.

The lower stacked structure 10 may include a first lower semiconductor layer 11 and a second lower semiconductor layer 12 that are stacked alternately on the substrate 100 along the third direction DR3. The upper stacked structure 20 may include a first upper semiconductor layer 21 and a second upper semiconductor layer 22 that are stacked alternately along the third direction DR3. The intermediate insulating pattern 115 may be formed between the lower stacked structure 10 and the upper stacked structure 20.

The substrate 100 may be bulk silicon or silicon-on-insulator (SOI). The substrate 100 may be a silicon substrate or may include other materials, for example, but is not limited to, silicon germanium, silicon germanium-on-insulator (SGOI), indium antimonide, lead telluride, indium arsenide, indium phosphide, gallium arsenide or gallium antimonide.

The first lower semiconductor layer 11 and the first upper semiconductor layer 21 may include a material having an etching selectivity with respect to a material of the second lower semiconductor layer 12 and the second upper semiconductor layer 22. For example, each of the second lower semiconductor layer 12 and the second upper semiconductor layer 22 may include silicon, and each of the first lower semiconductor layer 11 and the first upper semiconductor layer 21 may include silicon germanium.

In some embodiments, a fin pattern 110 may be formed between the substrate 100 and the lower stacked structure 10. The fin pattern 110 may extend long in the first direction DR1. In some embodiments, a field insulating film 105 that covers at least a part of the side face of the fin pattern 110 may be formed.

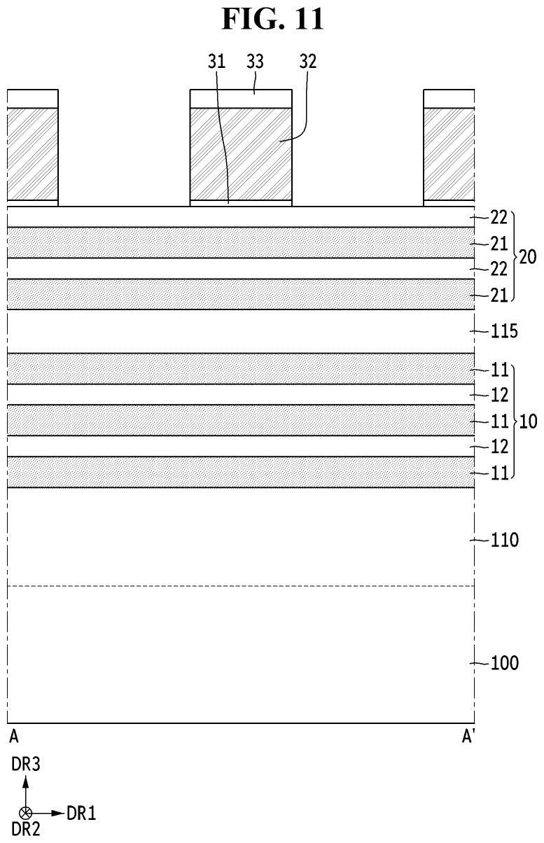

Referring to FIGS. 11 to 13, a dummy gate insulating film 31, a dummy gate electrode 32, and a dummy capping pattern 33 may be formed on the upper stacked structure 20. The dummy gate electrodes 32 may extend in the second direction DR2 and may be spaced apart in the first direction DR1. The dummy gate insulating film 31 may be formed between the dummy gate electrode 32 and the upper stacked structure 20. The dummy capping pattern 33 may be formed on the dummy gate electrode 32.

For example, an insulating film may be formed along the upper side of the field insulating film 105, the side walls of the fin pattern 110 protruding from the field insulating film 105, the side walls of the lower stacked structure 10, the side walls of the intermediate insulating pattern 115, and the side walls and upper side of the upper stacked structure 20. A conductive film may be formed on the insulating film, and a dummy capping pattern 33 extending long in the second direction DR2 may be formed above the conductive film on the upper stacked structure 20 and the field insulating film 105. The insulating film and the conductive film may be patterned using the dummy capping pattern 33 as a mask to form a dummy gate insulating film 31 and a dummy gate electrode 32.

The dummy gate insulating film 31 may include, for example, but is not limited to, silicon oxide. The dummy gate electrode 32 may include, for example, but is not limited to, polysilicon. The dummy capping pattern 33 may include, for example, but is not limited to, silicon nitride.

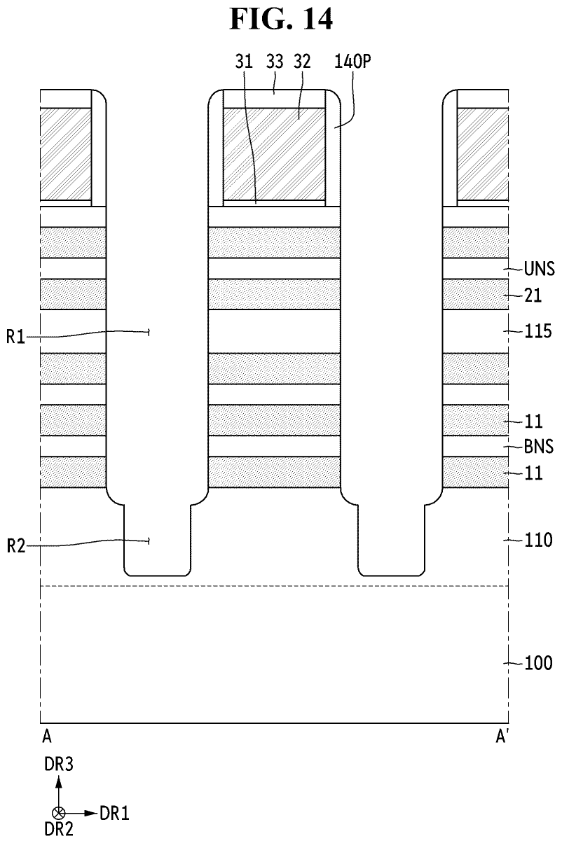

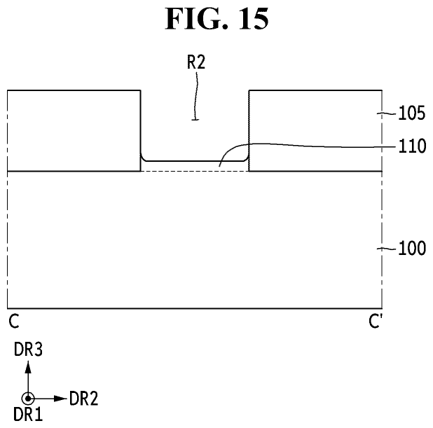

Referring to FIGS. 14 and 15, a preliminary gate spacer 140P may be formed on the upper stacked structure 20 on the side wall of the dummy gate electrode 32. The preliminary gate spacer 140P may extend along the side wall of the dummy gate insulating film 31, the side wall of the dummy gate electrode 32, and the side wall of the dummy capping pattern 33.

Next, a plurality of first recesses R1 may be formed inside the upper stacked structure (20 of FIGS. 11 to 13), the intermediate insulating pattern 115, and the lower stacked structure (10 of FIGS. 11 to 13), by using the dummy gate electrode 32, the dummy capping pattern 33, and the preliminary gate spacer 140P as masks. The first recesses R1 may be formed between adjacent dummy gate electrodes 32. The second lower semiconductor layer 12 may be separated by the first recesses R1 to form a lower channel pattern BNS, and the second upper semiconductor layer 22 may be separated to form an upper channel pattern UNS.

Next, a second recess R2 may be formed under the first recess R1. The second recess R2 may be formed inside (e.g., may extend into) the fin pattern 110. For example, the size of the second recess R2 in the first direction DR1 may be, but is not limited to, smaller than the size of the first recess R1.

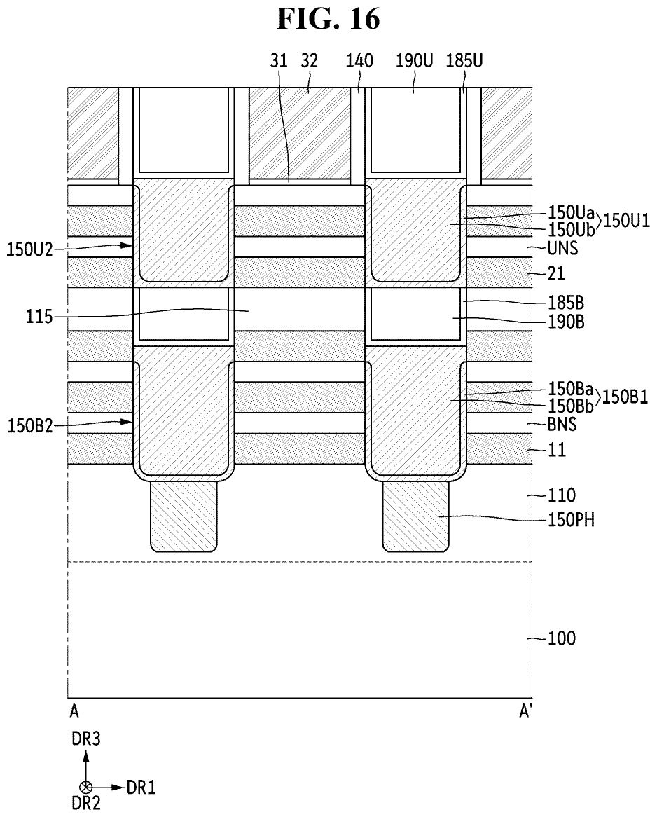

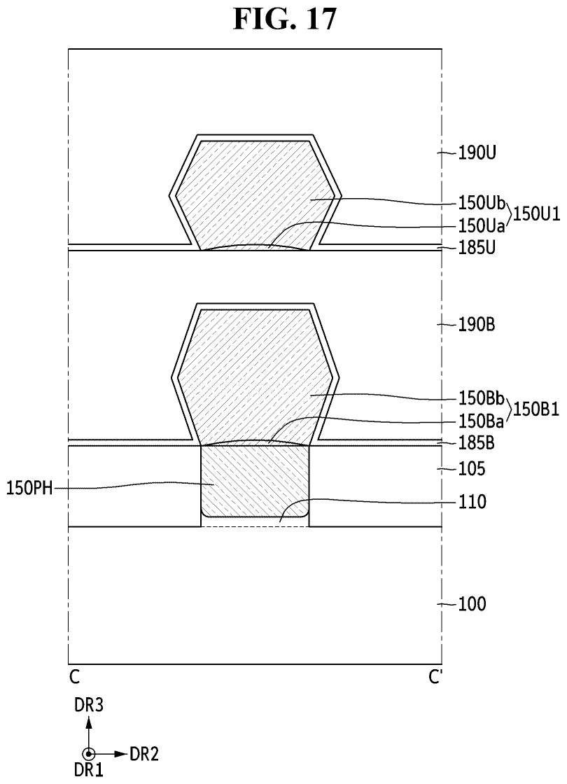

Referring to FIGS. 16 and 17, a sacrificial pattern 150PH may be formed inside the second recess (R2 of FIGS. 14 and 15), and lower source/drain patterns 150B1 and 150B2, a lower source/drain etching stop film 185B, a lower front interlayer insulating film 190B, and upper source/drain patterns 150U1 and 150U2 may be formed inside the first recess (R1 of FIG. 14). An upper source/drain etching stop film 185U and an upper front interlayer insulating film 190U may be formed on the upper source/drain patterns 150U1 and 150U2. The lower source/drain patterns 150B1 and 150B2 may include a first lower source/drain pattern 150B1 and a second lower source/drain pattern 150B2 that are formed inside different first recesses (R1 of FIG. 14). The upper source/drain patterns 150U1 and 150U2 may include a first upper source/drain pattern 150U1 on the first lower source/drain pattern 150B1 and a second lower source/drain pattern 150B2 on the second lower source/drain pattern 150B2.

The sacrificial pattern 150PH may be formed by an epitaxial growth process. The sacrificial pattern 150PH may be grown, for example, from the substrate 100 in a bottom-up manner.

The lower source/drain patterns 150B1 and 150B2 may be formed on the sacrificial pattern 150PH. The lower source/drain patterns 150B1 and 150B2 may be formed on the side walls of the lower channel pattern BNS and the side walls of the first lower semiconductor layer 11. The lower source/drain patterns 150B1 and 150B2 may be in contact with the lower channel pattern BNS. For example, the lower source/drain patterns 150B1 and 150B2 may be formed by an epitaxial growth process which uses at least one of the lower sacrificial pattern 150PH and the lower channel pattern BNS exposed by the first recess (R1 of FIG. 14) as a seed layer.

In some embodiments, the second recess R2 and the sacrificial pattern 150PH may not be formed.

The lower source/drain patterns 150B1 and 150B2 may include p-type dopants. For example, in the process in which the lower source/drain patterns 150B1 and 150B2 are formed, the p-type dopants may be implanted in situ. As another example, after the lower source/drain patterns 150B1 and 150B2 are formed, p-type dopants may be implanted into the lower source/drain patterns 150B1 and 150B2.

The lower source/drain etching stop film 185B may be formed along the upper sides of the field insulating film 105 and the lower source/drain patterns 150B1 and 150B2. The lower front interlayer insulating film 190B may be formed on the lower source/drain etching stop film 185B. The upper side of the lower interlayer insulating film 190B may be, but is not limited to, substantially on the same plane as the upper side of the intermediate insulating pattern 115.

The upper source/drain patterns 150U1 and 150U2 may be formed on the lower front interlayer insulating film 190B. The lower front interlayer insulating film 190B may be between the upper source/drain patterns 150U1 and 150U2 and the lower source/drain patterns 150B1 and 150B2. The upper source/drain patterns 150U1 and 150U2 may be formed on the side walls of the upper channel pattern UNS and the side walls of the first upper semiconductor layer 21. The upper source/drain patterns 150U1 and 150U2 may be in contact with the upper channel pattern UNS. For example, the upper source/drain patterns 150U1 and 150U2 may be formed by an epitaxial growth process which uses the upper channel pattern UNS exposed by the first recess (R1 of FIG. 14) as a seed layer.

The upper source/drain patterns 150U1 and 150U2 may include n-type dopants. For example, in the process of forming the upper source/drain patterns 150U1 and 150U2, n-type dopants may be implanted in situ. As another example, after the upper source/drain patterns 150U1 and 150U2 are formed, n-type dopants may be implanted into the upper source/drain patterns 150U1 and 150U2.

The upper source/drain etching stop film 185U may be formed along the upper sides of the upper source/drain patterns 150U1 and 150U2 and the lower front interlayer insulating film 190B. The upper front interlayer insulating film 190U may be formed on the upper source/drain etching stop film 185U.

Next, a part of the upper source/drain etching stop film 185U, a part of the upper front interlayer insulating film 190U, and the dummy gate capping pattern (33 of FIG. 14) may be removed to expose the upper side of the dummy gate electrode 32. While the upper side of the dummy gate electrode 32 is exposed, the gate spacer 140 may be formed. The upper side of the upper interlayer insulating film 190U may be, but is not limited to, substantially on the same plane as the upper side of the dummy gate electrode 32.

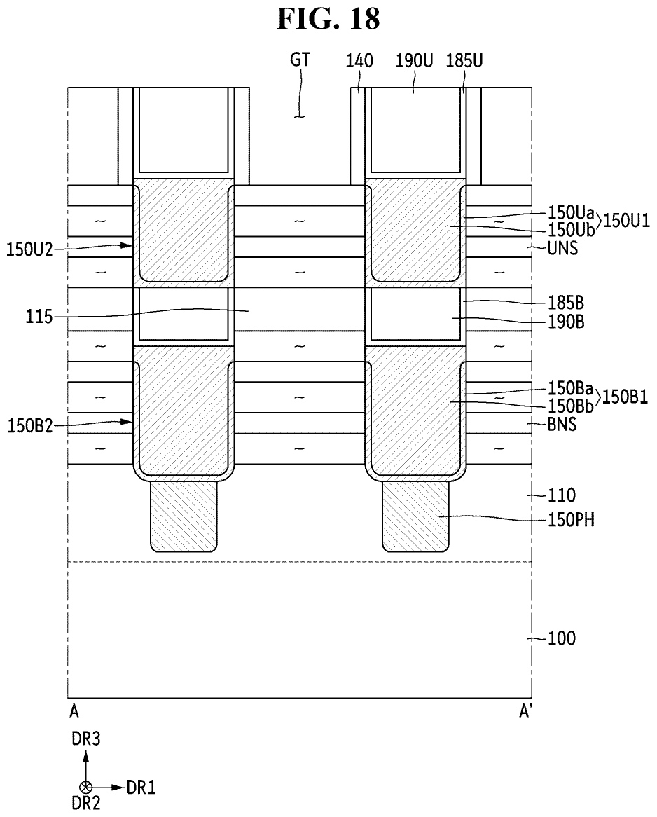

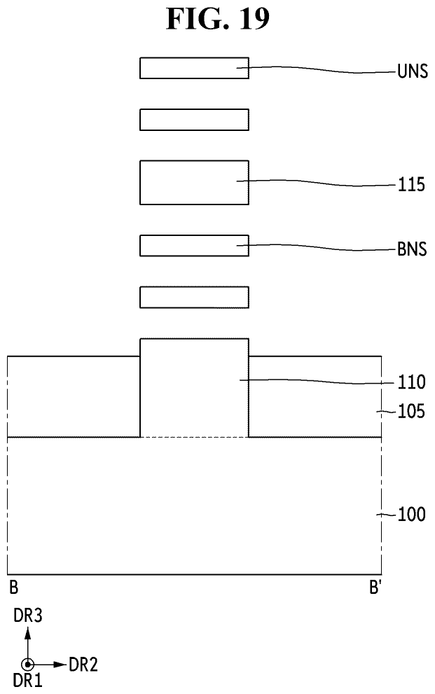

Referring to FIGS. 18 and 19, the dummy gate insulating film (31 of FIG. 16), the dummy gate electrode (32 of FIG. 16), the first lower semiconductor layer (11 of FIG. 16), and the first upper semiconductor layer (21 of FIG. 16) may be removed to form a gate trench GT.

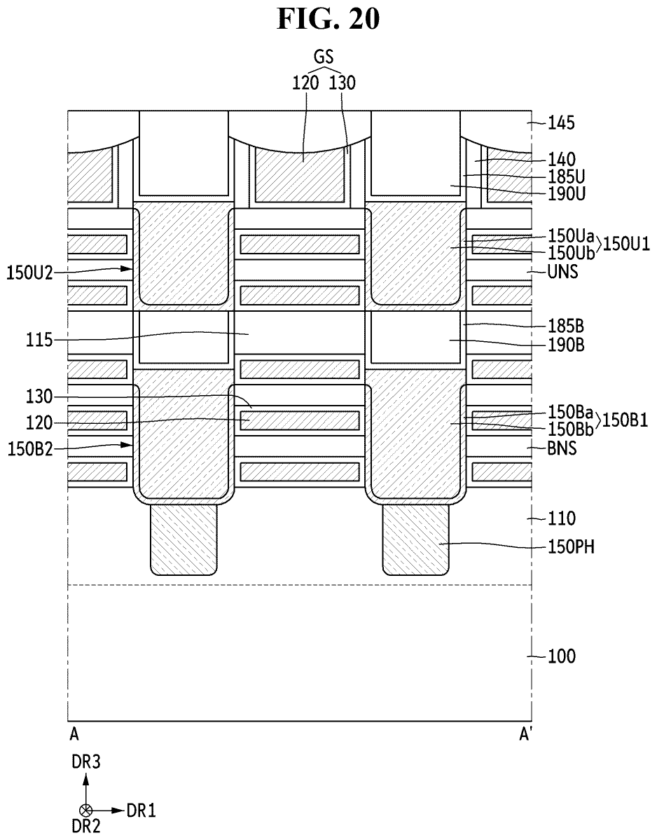

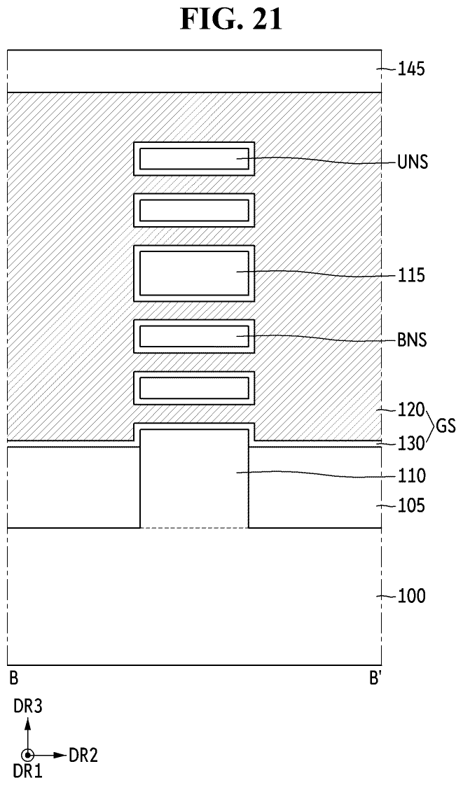

Referring to FIGS. 20 and 21, the gate insulating film 130 and the gate electrode 120 may be formed sequentially inside the gate trench (GT of FIG. 18). As a result, a gate structure GS that encloses the lower channel pattern BNS and the upper channel pattern UNS may be formed. Next, a gate capping pattern 145 that covers the upper side of the gate electrode 120 may be formed.

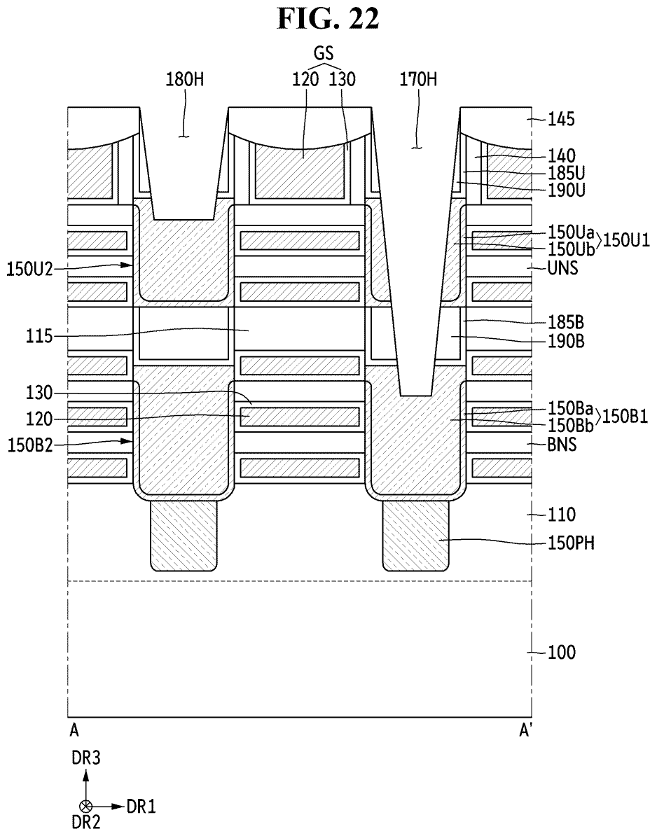

Referring to FIG. 22, a first contact hole 170H and a second contact hole 180H may be formed. The first contact hole 170H and the second contact hole 180H may expose different upper source/drain patterns 150U1 and 150U2, respectively. The bottom side of the first contact hole 170H and the bottom side of the second contact hole 180H may be disposed below the uppermost side of the upper channel pattern UNS.

The first contact hole 170H may extend in the third direction DR3. The first contact hole 170H may extend into the upper interlayer insulating film 190U, the first upper source/drain pattern 150U1, the lower interlayer insulating film 190B, the lower source/drain etching stop film 185B, and the first lower source/drain pattern 150B1. The bottom side of the first contact hole 170H may be disposed inside the first lower source/drain pattern 150B1. The first contact hole 170H may penetrate the upper interlayer insulating film 190U, the upper source/drain etching stop film 185U, the first upper source/drain pattern 150U1, the lower interlayer insulating film 190B, the lower source/drain etching stop film 185B, and a part of the first lower source/drain pattern 150B1. The first upper source/drain pattern 150U1 and the first lower source/drain pattern 150B1 may be exposed through the first contact hole 170H.

The second contact hole 180H may extend in the third direction DR3. The second contact hole 180H may extend into the upper interlayer insulating film 190U and the second upper source/drain pattern 150U2. The bottom side of the second contact hole 180H may be disposed inside the second upper source/drain pattern 150U2. The second contact hole 180H may penetrate the upper interlayer insulating film 190U, the upper source/drain etching stop film 185U, and a part of the second upper source/drain pattern 150U2. The second upper source/drain pattern 150U2 may be exposed through the second contact hole 180H.

Referring to FIGS. 23 and 24, a contact film 175 may be formed inside the first contact hole 170H and the second contact hole 180H. The contact film 175 may cover an upper side of the gate capping pattern 145.

The contact film 175 may be formed conformally along the first contact hole 170H and the second contact hole 180H. The contact film 175 may fill at least a part of each of the first contact hole 170H and the second contact hole 180H. The contact film 175 may extend along an upper side of the gate capping pattern 145.

The contact film 175 may include a metal material and may be deposited conformally. The contact film 175 may include, for example, molybdenum, tungsten, or the like.

The contact film 175 in the first contact hole 170H may include at least one first seam 171S therein. The first seam 171S may be formed in the process of forming the contact film 175. The first seam 171S may have a third size W3 in the third direction DR3.

The contact film 175 in the first contact hole 170H may include a plurality of first crystal grains G1.

A first upper contact silicide film 155U may be formed between the contact film 175 and the first upper source/drain pattern 150U1, a first lower contact silicide film 155 may be formed between the contact film 175 and the first lower source/drain pattern 150B1, and a second upper contact silicide film 156U may be formed between the contact film 175 and the second upper source/drain pattern 150U2.

Referring to FIGS. 25 and 26, an annealing process is performed on the contact film 175 in the first contact hole 170H. In some embodiments, the annealing process may include a hydrogen radical annealing process, for example, a plasma annealing process in a hydrogen atmosphere. The hydrogen radical annealing process may be performed at a temperature of 400° C. to 450° C., for a time of 5 minutes to 30 minutes, and under the condition that a power of 4.5 kV or more and 7.5 kV or less is provided.

The annealing process may include low-temperature soak annealing, flash lamp annealing, laser annealing, spike annealing, and/or rapid thermal annealing.

In some embodiments, the first seam (171S of FIGS. 23 and 24) may be removed from the contact film 175 in the first contact hole 170H by the annealing process.

Further, the first crystal grains (G1 of FIG. 24) of the contact film 175 in the first contact hole 170H are grown by the annealing process to form the second crystal grains G2. The first crystal grains (G1 of FIG. 24) may be merged to form the second crystal grains G2.

The average size of the second crystal grains of the contact film 175 in the first contact hole 170H of FIG. 26 may be larger than the average size of the first crystal grains of the contact film 175 in the first contact hole 170H of FIG. 24. For example, the average size of the first crystal grains may indicate the average of the maximum size of each of the first crystal grains G1 of FIG. 24, and the average size of the second crystal grains may mean the average of the maximum size of each of the second crystal grains G2 of FIG. 26.

The first crystal grains G1 of FIG. 24 and the second crystal grains G2 of FIG. 26 may be analyzed, for example, through transmission electron microscopy (TREM) or precession electron diffraction (PED) analysis.

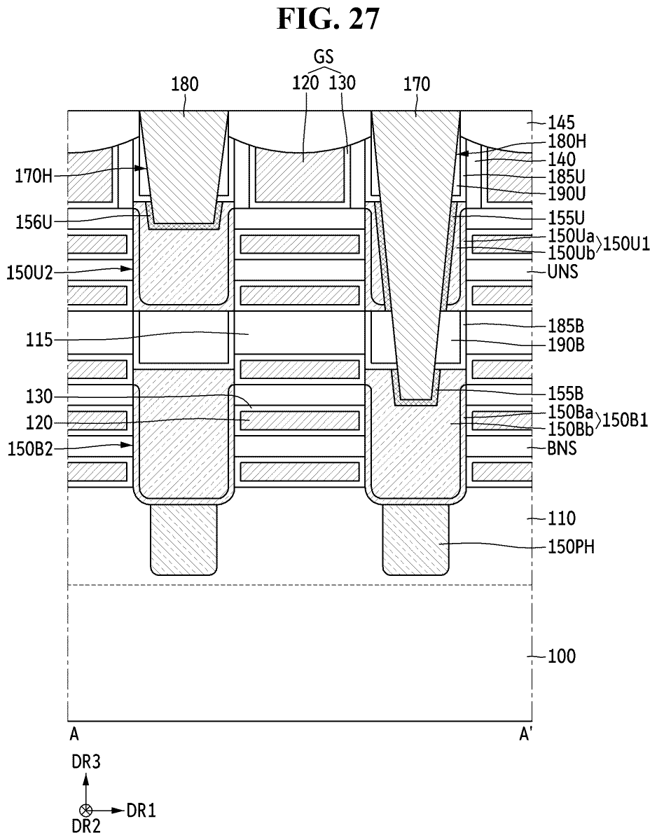

Referring to FIG. 27, a planarization process may be performed on the contact film (175 of FIGS. 25 and 26) to form a first front source/drain contact 170 and a second front source/drain contact 180. The first front source/drain contact 170 may fill the first contact hole 170H, and the second front source/drain contact 180 may fill the second contact hole 180H.

The contact film 175 that fills the first contact hole 170H of FIGS. 25 and 26 may be defined as the first front source/drain contact 170 of FIG. 27, and the contact film 175 that fills the second contact hole 180H of FIGS. 25 and 26 may be defined as the second front source/drain contact 180 of FIG. 27. Thus, in some embodiments, the first front source/drain contact 170 may not include a seam therein by the annealing process described using FIGS. 25 and 26. The average size of the second crystal grains of the first front source/drain contact 170 may be the same as the average size of the second crystal grains of the contact film 175 in the first contact hole 170H of FIG. 26. That is, the average size of the second crystal grains of the first front source/drain contact 170 may be larger than the average size of the first crystal grains of the contact film 175 in the first contact hole 170H of FIG. 24. Moreover, in some embodiments, the average size of the second crystal grains of the first front source/drain contact 170 may be larger than the average size of the crystal grains of the second front source/drain contact 180.

Referring to FIGS. 2 to 4, a front insulating film 191, and a front wiring structure 195 in the front insulating film 191 may be formed on the gate capping pattern 145, the first front source/drain contact 170, and the second front source/drain contact 180. The front wiring structure 195 may be connected to the first and second front source/drain contacts 170 and 180.

The substrate (100 of FIG. 27) and the fin pattern (110 of FIG. 27) may be removed. Accordingly, the gate structure GS, the lower source/drain patterns 150B1 and 150B2, and the sacrificial pattern 150PH may be exposed.

The insulating pattern 290P and the back interlayer insulating film 290 may be formed on the gate structure GS, the lower source/drain patterns 150B1 and 150B2, and the sacrificial pattern 150PH.

The first back source/drain contact 70 may be formed inside the back interlayer insulating film 290 and the insulating pattern 290P. The sacrificial pattern (150PH of FIG. 27) under the second lower source/drain pattern 150B2 may be exposed through an etching process. The exposed second sacrificial pattern (150PH of FIG. 27) may be removed to expose the second lower source/drain pattern 150B2. Next, the second back source/drain contact 80 connected to the second lower source/drain pattern 150B2 may be formed.

A first back insulating film 291, and a back connecting contact 60 in the first back insulating film 291 may be formed on the back interlayer insulating film 290. The back connecting contact 60 may be connected to the second back source/drain contact 80.

A second back insulating film 292, and a back connecting via 55 in the second back insulating film 292 may be formed on the first back insulating film 291 and the back connecting contact 60. The back connecting via 55 may be connected to the back connecting contact 60.

Next, a third back insulating film 293, and a back wiring line 50 in the third back insulating film 293 may be formed on the second back insulating film 292 and the back connecting via 55. The back wiring line 50 may be connected to the second back source/drain contact 80.

Referring to FIGS. 9 to 27, when a seam exists inside the first front source/drain contact 170, the resistance of the first front source/drain contact 170 may increase due to the seam. Also, the stress applied to the upper channel pattern UNS adjacent to the first front source/drain contact 170 decreases, and the channel performance of the upper channel pattern UNS used as a channel region of the NMOS may decrease.

However, the method for manufacturing a semiconductor device according to some embodiments includes an annealing process, for example, a hydrogen radical annealing process, which is performed on the contact film 175 in the first contact hole 170H. Through the annealing process, the first seam 171S is removed, and the first front source/drain contact 170 including the second crystal grain G2 of a relatively large size may be formed. Therefore, the resistance of the first front source/drain contact 170 may be improved and/or decreased, and a tensile stress may be applied to the upper channel pattern UNS to improve and/or enhance the channel performance of the upper channel pattern UNS used as a channel region of the NMOS. Therefore, a semiconductor device with improved and/or enhanced performance may be provided.

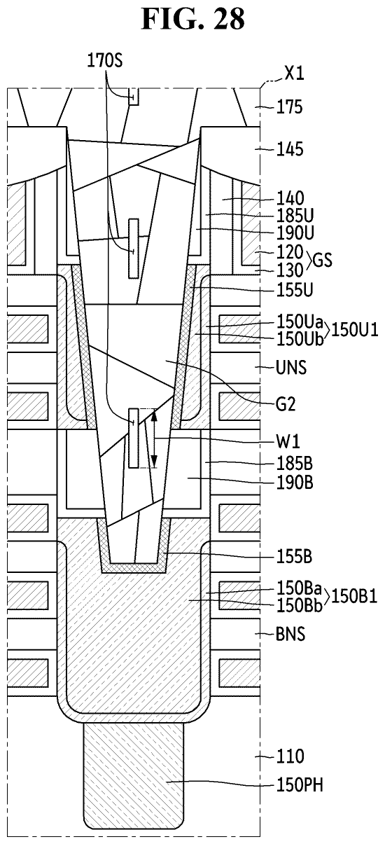

FIG. 28 is a diagram for explaining a method for manufacturing a semiconductor device according to some embodiments. For convenience of explanation, differences from those described using FIGS. 1 to 27 will be mainly described. For reference, FIG. 28 is an enlarged view of a region X1 of FIG. 25.

Referring to FIGS. 25 and 28, an annealing process is performed on the contact film 175 inside the first contact hole 170H.

In some embodiments, the size of the first seam (171S of FIGS. 23 and 24) of the contact film 175 in the first contact hole 170H decreases by the annealing process, and at least one first seam 170S may be formed. The first size W1 of the first seam 170S in the third direction DR3 may be smaller than the third size (W3 of FIG. 23) of the first seam (171S of FIGS. 23 and 24) in the third direction DR3. When a plurality of first seams 170S are formed, the first seams 170S may be spaced apart, for example, in the third direction DR3. Also, when the plurality of first seams 170S are formed, the first size W1 of each first seam 170S in the third direction DR3 may be smaller than the third size (W3 of FIG. 23) of the first seam (171S of FIGS. 23 and 24) in the third direction DR3.

Next, referring to FIG. 5, a planarization process may be performed on the contact film (175 of FIGS. 25 and 26) to form the first front source/drain contact 170 and the second front source/drain contact 180.

The contact film 175 that fills the first contact hole H1 of FIGS. 25 and 28 may be defined as the first front source/drain contact 170 of FIG. 5, and the contact film 175 that fills the second contact hole 180H of FIG. 25 may be defined as the second front source/drain contact 180 of FIG. 5. Thus, in some embodiments, the first front source/drain contact 170 may include at least one first seam 170S therein. The average size of the second crystal grain of the first front source/drain contact 170 may be the same as the average size of the second crystal grains of the contact film 175 inside the first contact hole 170H of FIG. 28. That is, the average size of the second crystal grains of the first front source/drain contact 170 may be larger than the average size of the first crystal grains of the contact film 175 inside the first contact hole 170H of FIG. 24.

Next, as described above using FIGS. 2 to 4, the front insulating film 191 and the front wiring structure 195 may be formed, the substrate (100 of FIG. 25) and the fin pattern (110 of FIG. 25) may be removed, and the insulating pattern 290P, the back interlayer insulating film 290, the second back source/drain contact 80, the first back insulating film 291, the back connecting contact 60, the second back insulating film 292, the back connecting via 55, the third back insulating film 293, and the back wiring line 50 may be formed.

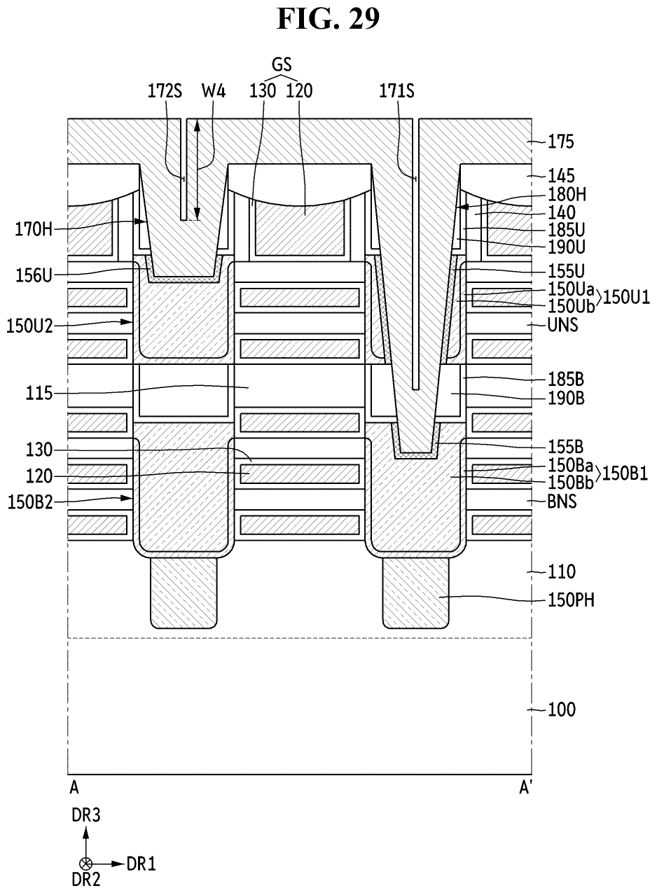

FIG. 29 is a diagram for explaining a method for manufacturing a semiconductor device according to some embodiments. For convenience of explanation, differences from those described using FIGS. 1 to 28 will be mainly described. For reference, FIG. 29 may be a manufacturing method that proceeds after FIG. 22.

Referring to FIG. 29, the contact film 175 may be formed inside the first contact hole 170H and the second contact hole 180H. The contact film 175 may extend conformally along the first contact hole 170H, the second contact hole 180H, and the upper side of the gate capping pattern 145.

In some embodiments, the contact film 175 inside the second contact hole 180H may include at least one second seam 172S therein. The second seam 172S may be formed in the process of forming the contact film 175. The second seam 172S may have a fourth size W4 in the third direction DR3.

Next, referring to FIG. 6, in some embodiments, an annealing process may be performed on the contact film (175 of FIG. 29) in the first contact hole (170H of FIG. 29) and the contact film (175 of FIG. 29) in the second contact hole (180H of FIG. 29). Next, a planarization process may be performed on the contact film (175 of FIG. 29) to form the first front source/drain contact 170 and the second front source/drain contact 180. The contact film 175 that fills the first contact hole 170H of FIG. 29 may be defined as the first front source/drain contact 170 of FIG. 6, and the contact film 175 that fills the second contact hole 180H of FIG. 29 may be defined as the second front source/drain contact 180 of FIG. 6.

The size of the second seam (172S of FIG. 29) of the contact film (175 of FIG. 29) in the second contact hole (180H of FIG. 29) decreases by the annealing process, and at least one second seam 180S may be formed. The second size W2 of the second seam 180S in the third direction DR3 may be smaller than the fourth size (W4 of FIG. 29) of the second seam (172S of FIG. 29) in the third direction DR3. When a plurality of second seams 180S are formed, the second seams 180S may be spaced apart, for example, in the third direction DR3. Also, when the plurality of second seams 180S are formed, the second size W2 of each second seam 180S in the third direction DR3 may be smaller than the fourth size (W4 of FIG. 29) of the second seam (172S of FIG. 29) in the third direction DR3.

Also, the first crystal grains of the contact film (175 of FIG. 29) inside the second contact hole (180H of FIG. 29) are grown by the annealing process, and the second crystal grains may be formed. The average size of the second crystal grains of the second front source/drain contact 180 of FIG. 6 may be larger than the average size of the first crystal grains of the contact film 175 in the second contact hole 180H of FIG. 29. For example, the average size of the first crystal grains may mean the average of the maximum size of each first crystal grain of the contact film 175 in the second contact hole 180H of FIG. 29, and the average size of the second crystal grain may mean the average of the maximum size of each second crystal grain of each second front source/drain contact 180 of FIG. 6.

Next, as described above using FIGS. 2 to 4, the front insulating film 191 and the front wiring structure 195 may be formed, the substrate (100 of FIG. 29) and the fin pattern (110 of FIG. 29) may be removed, and the insulating pattern 290P, the back interlayer insulating film 290, the second back source/drain contact 80, the first back insulating film 291, the back connecting contact 60, the second back insulating film 292, the back connecting via 55, the third back insulating film 293, and the back wiring line 50 may be formed.

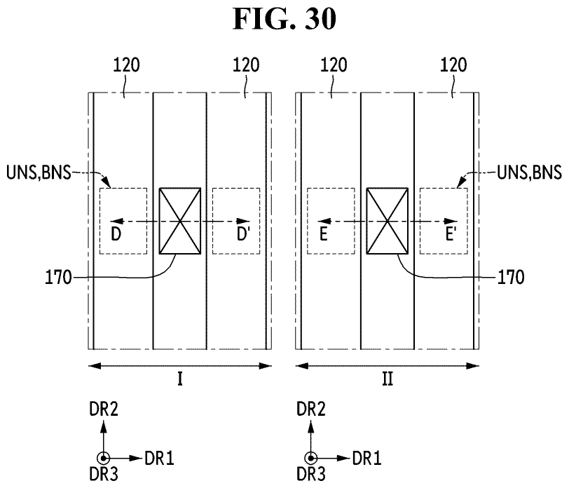

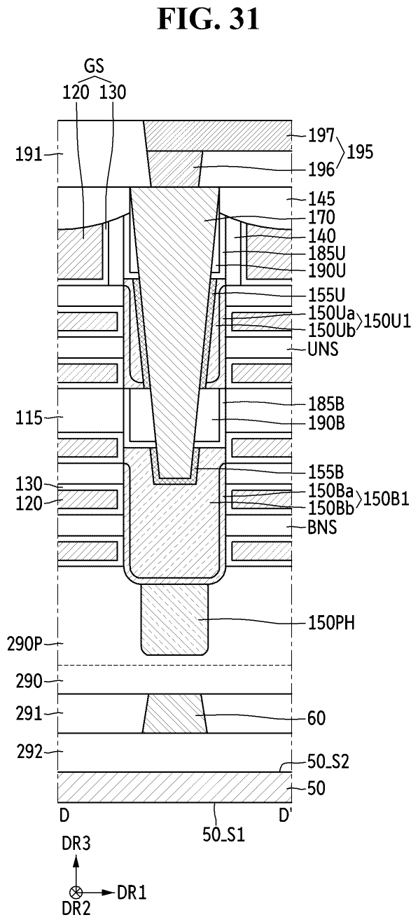

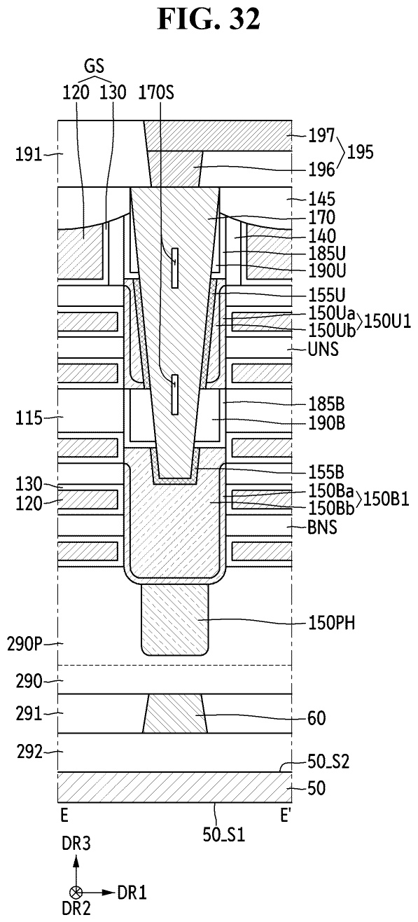

FIG. 30 is a layout diagram for explaining a semiconductor device according to some embodiments. FIG. 31 is a cross-sectional view taken along D-D′ of FIG. 30. FIG. 32 is a cross-sectional view taken along E-E′ of FIG. 30. For convenience of explanation, differences from contents described using FIGS. 1 to 8 will be mainly described.

Referring to FIGS. 30 to 32, a semiconductor device according to some embodiments may include a first region I and a second region II. The first region I and the second region II may be regions adjacent to each other or may be regions spaced apart from each other. The first region I and the second region II may be regions that perform the same function or may be regions that perform different functions.

In some embodiments, the first front source/drain contact 170 disposed in the first region I may not include a seam therein, and the first front source/drain contact 170 disposed in the second region II may include at least one first seam 170S therein.

The stress applied to the upper channel pattern UNS adjacent to the first front source/drain contact 170 in the first region I may be different from the stress applied to the upper channel pattern UNS adjacent to the first front source/drain contact 170 in the second region II. For example, the stress applied to the upper channel pattern UNS adjacent to the first front source/drain contact 170 in the first region I may be greater than the stress applied to the upper channel pattern UNS adjacent to the first front source/drain contact 170 in the second region II. The upper channel pattern UNS adjacent to the first front source/drain contact 170 in the first region I, and the upper channel pattern UNS adjacent to the first front source/drain contact 170 in the second region II may differ from each other in at least one of d-spacing (i.e., a pitch) and strain rate. The d-spacing and strain rate may be analyzed through GPA (Geometric Phase Analysis). The average size of the crystal grains of each first front source/drain contact 170 disposed in the first region I and the first front source/drain contact 170 disposed in the second region II may be equal to or different from each other.

In some embodiments, each of the first front source/drain contact 170 disposed in the first region I and the first front source/drain contact 170 disposed in the second region II may not include a seam. In some embodiments, each of the first front source/drain contact 170 disposed in the first region I and the first front source/drain contact 170 disposed in the second region II may include at least one first seam 170S. In this case, the placement, number, size, or the like of the first seams 170S included in each of the first front source/drain contact 170 disposed in the first region I and the first front source/drain contact 170 disposed in the second region II may be the equal to or different from each other.

While aspects of embodiments have been particularly shown and described, it will be understood that various changes in form and details may be made therein without departing from the spirit and scope of the following claims.

What is claimed is:

1. A method for manufacturing a semiconductor device, the method comprising:
providing a lower channel pattern, an intermediate insulating pattern, and an upper channel pattern, which are stacked sequentially on a substrate along a vertical direction;
forming a lower source/drain pattern connected to the lower channel pattern;
forming an upper source/drain pattern connected to the upper channel pattern;
forming a gate structure which surrounds the lower channel pattern and the upper channel pattern;
forming a contact hole extending into the upper source/drain pattern and the lower source/drain pattern;
forming a contact film in the contact hole; and
performing an annealing process on the contact film to form a front source/drain contact.

2. The method for manufacturing the semiconductor device of claim 1, wherein the upper source/drain pattern and the lower source/drain pattern include dopants of different conductivity types.

3. The method for manufacturing the semiconductor device of claim 1, wherein the annealing process comprises a hydrogen radical annealing process.

4. The method for manufacturing the semiconductor device of claim 1, wherein the contact film includes a seam, and the annealing process comprises removing the seam so that the front source/drain contact does not include the seam.

5. The method for manufacturing the semiconductor device of claim 1, wherein the contact film includes a first seam,
wherein the front source/drain contact includes a second seam, and
wherein a size of the second seam along the vertical direction is smaller than a size of the first seam along the vertical direction.

6. The method for manufacturing the semiconductor device of claim 1, wherein the contact film includes a first seam,
wherein the front source/drain contact includes a plurality of second seams, and
wherein each of the plurality of second seams along the vertical direction is smaller than the first seam along the vertical direction.

7. The method for manufacturing the semiconductor device of claim 1, wherein an average crystal grain size of the contact film is smaller than an average crystal grain size of the front source/drain contact.

8. The method for manufacturing the semiconductor device of claim 1, wherein the contact film is formed conformally along the contact hole.

9. The method for manufacturing the semiconductor device of claim 1, further comprising forming a sacrificial pattern in the substrate,
wherein the lower source/drain pattern is formed on the sacrificial pattern.

10. The method for manufacturing the semiconductor device of claim 1, further comprising:
removing the substrate to expose the lower channel pattern and the lower source/drain pattern;
forming a back interlayer insulating film on the exposed lower channel pattern and the exposed lower source/drain pattern; and
forming a back source/drain contact that penetrates the back interlayer insulating film and is connected to the lower source/drain pattern.

11. The method for manufacturing the semiconductor device of claim 10, further comprising forming a back insulating film on the back interlayer insulating film, and a back wiring line in the back insulating film,
wherein the back wiring line is not electrically connected to the back source/drain contact.

12. A method for manufacturing a semiconductor device, the method comprising:
providing a lower channel pattern, an intermediate insulating pattern, and an upper channel pattern, which are stacked sequentially along a vertical direction;
forming a lower source/drain pattern including a p-type dopant on a side face of the lower channel pattern;
forming a lower front interlayer insulating film on the lower source/drain pattern;
forming an upper source/drain pattern including an n-type dopant on a side face of the upper channel pattern, the lower front interlayer insulating film being between the lower source/drain pattern and the upper source/drain pattern;
forming an upper front interlayer insulating film on the upper source/drain pattern;
forming a gate structure that encloses the lower channel pattern and the upper channel pattern;
forming a contact hole that penetrates the upper front interlayer insulating film and exposes the upper source/drain pattern, a bottom side of the contact hole being below an uppermost side of the upper channel pattern;
forming a contact film in the contact hole; and
performing an annealing process on the contact film to form a front source/drain contact.

13. The method for manufacturing the semiconductor device of claim 12, wherein the annealing process comprises a hydrogen radical annealing process.

14. The method for manufacturing the semiconductor device of claim 12, wherein the contact hole further penetrates the upper source/drain pattern and the lower front interlayer insulating film, and
wherein the lower source/drain pattern is exposed through the contact hole.

15. The method for manufacturing the semiconductor device of claim 12, wherein the contact film includes a seam, and the front source/drain contact does not include the seam.

16. The method for manufacturing the semiconductor device of claim 12, wherein the contact film includes a first seam,
wherein the front source/drain contact includes a second seam, and
wherein a size of the second seam along the vertical direction is smaller than a size of the first seam along the vertical direction.

17. The method for manufacturing the semiconductor device of claim 12, wherein an average crystal grain size of the contact film is smaller than an average crystal grain size of the front source/drain contact.

18. A method for manufacturing a semiconductor device, the method comprising:
providing a lower stacked structure including a first lower semiconductor layer and a second lower semiconductor layer stacked alternately along a vertical direction, on a substrate;
forming an intermediate insulating pattern on the lower stacked structure;
forming an upper stacked structure including a first upper semiconductor layer and a second upper semiconductor layer stacked alternately along the vertical direction, on the intermediate insulating pattern;
forming a plurality of first recesses which penetrate the lower stacked structure, the intermediate insulating pattern, and the upper stacked structure;
forming a lower source/drain pattern, a lower front interlayer insulating film, and an upper source/drain pattern which are stacked sequentially along the vertical direction, in each of the plurality of first recesses, the lower source/drain pattern including a first lower source/drain pattern and a second lower source/drain pattern in different first recesses of the plurality of first recesses, and the upper source/drain pattern including a first upper source/drain pattern on the first lower source/drain pattern, and a second upper source/drain pattern on the second lower source/drain pattern;
removing the first lower semiconductor layer and the first upper semiconductor layer to form a gate trench;
forming a gate structure which is provided in the gate trench;
forming a first contact hole which exposes the first upper source/drain pattern and the first lower source/drain pattern;
forming a second contact hole which exposes the second upper source/drain pattern;
forming a contact film in the first contact hole and the second contact hole; and
performing an annealing process on at least a part of the contact film to form a first front source/drain contact in the first contact hole and a second front source/drain contact in the second contact hole.

19. The method for manufacturing the semiconductor device of claim 18, wherein the contact film includes a seam, and
wherein the first front source/drain contact and the second front source/drain contact do not include the seam.

20. The method for manufacturing the semiconductor device of claim 18, wherein the contact film includes a first seam,
wherein the first front source/drain contact includes a second seam, and
wherein the second front source/drain contact does not include the seam.
